(19) United States
(12) Patent Application Publication
(10) Pub. No.: US 2023/0276676 A1
(43) Pub. Date: Aug. 31, 2023

(54) DISPLAY DEVICE

(71) Applicant: Samsung Display Co., LTD., Yongin-si (KR)

(72) Inventors: Min Soo KIM, Seoul (KR); YOONA KIM, Hwaseong-si (KR)

(73) Assignee: Samsung Display Co., LTD., Yongin-si (KR)

(21) Appl. No.: 18/092,481

(22) Filed: Jan. 3, 2023

(30) Foreign Application Priority Data
Feb. 25, 2022 (KR) 10-2022-0025368

(51) Int. Cl. H10K 59/35

(52) U.S. Cl. CPC H10K 59/353

(57) ABSTRACT

A display device includes: a substrate; and a plurality of first pixels, a plurality of second pixels, and a plurality of third pixels disposed on the substrate. Two of the plurality of first pixels and two of the plurality of third pixels are disposed at corner of a virtual first quadrangle, one of the plurality of second pixels is disposed within the virtual first quadrangle, and a center of the virtual first quadrangle does not overlap a center of the one of the plurality of second pixels.

### CROSS-REFERENCE TO RELATED APPLICATION(S)

This application claims priority to and the benefits of Korean Patent Application No. 10-2022-0025368 under 35 U.S.C. § 119, filed on Feb. 25, 2022, in the Korean Intellectual Property Office (KIPO), the entire contents of which are incorporated herein by reference.

### BACKGROUND

### 1. Technical Field

Embodiments relate to a display device.

### 2. Description of the Related Art

Recently, a light emitting diode display has attracted attention as a device for displaying an image. Since the light emitting diode display has a self-emission characteristic and does not require an additional light source, the thickness and the weight the light emitting diode display are more readily reduced as compared to a liquid crystal display device. Further, the light emitting display device has high-quality characteristics such as low power consumption, high luminance, and high response speed.

Generally, a light emitting display device includes a plurality of pixels emitting lights of different colors, and the plurality of pixels emit light to display an image.

Here, each pixel is a minimum unit for displaying an image. A power line such as a gate line, a data line, and a driving power line for driving each pixel and an insulating layer such as a pixel defining layer for defining an area (or a shape) of each pixel are positioned between neighboring pixels.

The light emitting display device is widely used. Thus, various methods for designing the shape of the light emitting display device have been developed, and functions for connecting or linking with the light emitting display device have been developed.

The above information disclosed in this Background section is only for enhancement of understanding of the background of the invention, and therefore it may contain information that does not form the prior art that is already known in this country to a person of ordinary skill in the art.

### SUMMARY

Embodiments provide a display device capable of improving space efficiency by providing a pixel arrangement structure including gaps between pixels that are variously formed.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include: a substrate; and a plurality of first pixels, a plurality of second pixels, and a plurality of third pixels, positioned on the substrate, wherein two of the plurality of first pixels and two of the plurality of third pixels may be disposed at corners of a virtual first quadrangle, one of the plurality of second pixels may be disposed within the virtual first quadrangle, and a center of the virtual first quadrangle may not overlap a center of the one of the plurality of second pixels.

Four of the plurality of second pixels may be disposed at corners of a virtual second quadrangle.

At least one of the virtual first quadrangle and the virtual second quadrangle may be a trapezoid.

The plurality of first pixels and the plurality of third pixels may be alternately disposed one by one along a first direction, and the plurality of first pixels and the plurality of third pixels may be alternately disposed one by one along a second direction perpendicular to the first direction.

The plurality of second pixels may include a first-second pixel, a second-second pixel, and a third-second pixel that are sequentially disposed on a same line, and a distance between the first-second pixel and the second-second pixel adjacent to each other may be different from a distance between the second-second pixel and the third-second pixel adjacent to each other.

The plurality of first pixels may include a first-first pixel, the plurality of third pixels may include a first-third pixel and a second-third pixel, the first-third pixel, the first-first pixel, and the second-third pixel may be sequentially disposed on a same line, and a distance between the first-first pixel and the first-third pixel adjacent to each other may be different from a distance between the first-first pixel and the second-third pixel adjacent to each other.

The virtual first quadrangle and the virtual second quadrangle may be trapezoids, the plurality of first pixels and the plurality of third pixels may be alternately disposed one by one along a first direction, a minimum distance and a maximum distance among distances between the plurality of first pixels and the plurality of third pixels in the first direction may be alternately repeated, and a minimum distance and a maximum distance among distances between the plurality of second pixels adjacent in a second direction perpendicular to the first direction may be alternately repeated.

In an embodiment, a display device may include: a substrate; and a plurality of first pixels, a plurality of second pixels, and a plurality of third pixels, disposed on the substrate, wherein four of the plurality of second pixels may be disposed at corners of a virtual first trapezoid, four of the plurality of second pixels may be disposed at corners of a virtual second trapezoid, a long side of the virtual first trapezoid and a long side of the virtual second trapezoid may overlap each other, each of the plurality of first pixels may be disposed at a center of the virtual first trapezoid, and each of the plurality of third pixels may be disposed at a center of the virtual second trapezoid.

In an embodiment, a display device may include: a substrate; and a plurality of first pixels, a plurality of second pixels, and a plurality of third pixels, disposed on the substrate, wherein four of the plurality of second pixels may be disposed at corer areas of a virtual first quadrangle, one of the plurality of first pixels or one of the plurality of third pixels may be disposed in the virtual first quadrangle, and a center of the one of the plurality of first pixels or a center of the one of the plurality of third pixels disposed in the virtual first quadrangle may not overlap a center of the virtual first quadrangle.

A distance between one of the plurality of second pixels and one of the plurality of first pixels adjacent to each other in a direction may be different from a distance between the one of the plurality of second pixels and another one of the plurality of first pixels adjacent to each other in the direction.

A distance between one of the plurality of second pixels and one of the plurality of third pixels adjacent to each other in a direction may be different from a distance between the one of the plurality of second pixels and another one of the plurality of third pixels adjacent to each other in the direction.

A first diagonal line of the virtual first quadrangle may pass through a center of one of the plurality of second pixels, and the plurality of first pixels and the plurality of third pixels may be alternately disposed in left areas and right areas with respect to the first diagonal line.

A first diagonal line of the virtual first quadrangle may pass through a center of the one of the plurality of first pixels or the one of the plurality of third pixels, and the plurality of second pixels may be alternately disposed in left areas and right areas with respect to the first diagonal line.

A first unit pixel may include one of the plurality of first pixels and one of the plurality of second pixels, and the first unit pixels may be alternately disposed in left areas and right areas with respect to a first diagonal line of the virtual first quadrangle.

Four of the plurality of second pixels may be disposed at corners of a virtual first rhombus, one of the plurality of second pixels may be disposed at a center of the virtual first rhombus, two of the plurality of first pixels or two of the plurality of third pixels may be disposed on a side of the virtual first rhombus, and the other two of the plurality of first pixels or the other two of the plurality of third pixels may be disposed in the virtual first rhombus.

Two of the four of the plurality of second pixels and the other two of the plurality of second pixels may be disposed at corners of a virtual second rhombus that contacts the virtual first rhombus, another one of the plurality of second pixels may be disposed in a center of the virtual second rhombus, the other two of the plurality of first pixels or the other two of the plurality of third pixels may be disposed on a side of the virtual second rhombus, and the plurality of first pixels or the plurality of third pixels may not be disposed in the virtual second rhombus.

The one of the plurality of first pixels or the one of the plurality of third pixels may be disposed on a virtual arc that connects two vertexes of the virtual first quadrangle.

In an embodiment, a display device may include: a substrate including a first area and a second area; a plurality of first pixels, a plurality of second pixels, and a plurality of third pixels, disposed on the substrate, wherein two of the plurality of first pixels and two of the plurality of third pixels may be disposed at corners of a virtual first quadrangle in the first area, one of the plurality of second pixels may be disposed within the virtual first quadrangle, a center of the virtual first quadrangle may overlap a center of the one of the plurality of second pixels, and one of the plurality of first pixels, one of the plurality of third pixels, and two of the plurality of second pixels may be disposed at corners of a virtual first rhombus in the second area.

The one of the plurality of first pixels and the one of the plurality of third pixels may be disposed at two vertexes of the virtual first rhombus in a first direction in the second area.

The two of the plurality of second pixels may be disposed at the other two vertexes of the virtual first rhombus in a second direction in the second area.

The two of the plurality of second pixels may be disposed on a side of the virtual first rhombus.

The two of the plurality of second pixels may be disposed in the virtual first rhombus.

Another one of the plurality of first pixels, another one of the plurality of third pixels, and the other two of the plurality of second pixels may be disposed at corners of a virtual second rhombus, and a shape of the one of the plurality of first pixels in the virtual first rhombus disposed in a first row and a shape of the another one of the plurality of third pixels in the virtual second rhombus disposed in a second row may be substantially same as each other.

The shape of the one of the plurality of first pixels in the virtual first rhombus may be different from a shape of the one of the plurality of third pixels in the virtual first rhombus, and a shape of the another one of the plurality of first pixels in the virtual second rhombus may be different from a shape of the another one of the plurality of third pixels in the virtual second rhombus.

The virtual first rhombus and the virtual second rhombus may not be disposed on a same line in a second direction.

A spacer may be disposed in a virtual triangle including corners, in which one of the plurality of first pixels, one of the plurality of second pixels, and one of the plurality of third pixels that are adjacent to each other at a shortest distance.

The virtual first rhombus and the virtual second rhombus may be disposed on a same line in a second direction.

A spacer may be disposed in a virtual quadrangle including corners, in which two of the plurality of first pixels and two of the plurality of third pixels that are adjacent to each other at a shortest distance.

Shapes of each of the plurality of first pixels, each of the plurality of second pixels, and each of the plurality of third pixels may be one of a circle, a quadrangle, a pentagon, and a hexagon.

In an embodiment, a display device may include: a substrate; and a plurality of first pixels, a plurality of second pixels, and a plurality of third pixels disposed on the substrate, wherein two of the plurality of second pixels, one of plurality of first pixels, and one of the plurality of third pixels may form a first unit, the first unit may include: a first sub-unit including the one of the plurality of first pixels and one of the two of the plurality of second pixels; and a second sub-unit including the one of the plurality of third pixels and another one of the two of the plurality of second pixels, and a size of each of the plurality of second pixels may be smaller than sizes of the plurality of first pixels and the plurality of third pixels.

Shapes of the first sub-unit and the second sub-unit may be substantially same as each other.

The first sub-unit and the second sub-unit may have shapes that are symmetrical to each other with respect to a virtual straight line disposed between the first sub-unit and the second sub-unit.

The first sub-unit and the second sub-unit may have shapes that are 180 degrees symmetrical with respect to a center point of the first unit.

The other two of the plurality of second pixels, another one of the plurality of first pixels, and another one of the plurality of third pixels may form a second unit, and shapes of the first unit and the second unit may be substantially same as each other.

The other two of the plurality of second pixels, another one of the plurality of first pixels, and another one of the plurality of third pixels may form a second unit, and the first unit and the second unit may have shapes that are symmetrical to each other with respect to a virtual straight line between the first unit and the second unit.

A shape of each of the plurality of second pixels may be a triangle, and a shape of each of the plurality of first pixels and a shape of each of the third pixels may be trapezoids.

A shape of each of the plurality of first pixels, a shape of each of the plurality of second pixels, and a shape of each of the plurality of third pixels may be rhombuses.

According to the embodiments, a pixel arrangement structure of a display device in which a gap between pixels is efficiently set is provided.

### BRIEF DESCRIPTION OF THE DRAWINGS

FIG. 1 is a schematic plan view illustrating a pixel arrangement of a display device according to an embodiment.

FIG. 2 to FIG. 54 are schematic plan views illustrating pixel arrangements according to other embodiments.

FIG. 55 is a schematic diagram of an equivalent circuit of a pixel according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

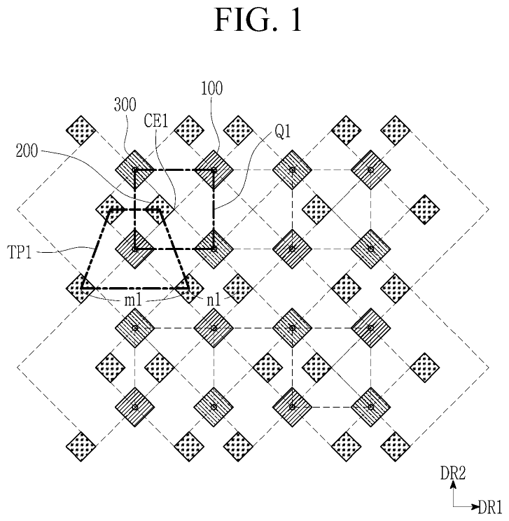

Hereinafter, a display device according to an embodiment will be described. FIG. 1 a schematic plan view illustrating a pixel arrangement of a display device according to an embodiment. Although it will be described in detail later, a pixel means a minimum unit for displaying an image, and each pixel may include one or more transistors and a light emitting element connected thereto. The invention relates to a method of arranging pixels of a display device, and the method of arranging the pixels will be described below.

Referring to FIG. 1, a pixel according to an embodiment may include a first pixel 100, a second pixel 200, and a third pixel 300. The first pixel 100 may be a pixel emitting red (R), the second pixel 200 may be a pixel emitting green (G), and the third pixel 300 may be a pixel emitting blue (B), but embodiments are not limited thereto. In an embodiment, a case in which the first pixel 100 emits red light (R), the second pixel 200 emits green light (G), and the third pixel 300 emits blue light (B) will be described as an example.

Referring to FIG. 1, two adjacent first pixels 100 and two adjacent third pixels 300 may form a virtual first quadrangle Q1. Referring to FIG. 1, in the virtual first quadrangle Q1, the first pixels 100 may be positioned at vertexes (e.g., opposite vertexes) symmetrical with respect to a center point CE1 of the virtual first quadrangle Q1, and the third pixels 300 may be positioned at vertexes (e.g., opposite vertexes) symmetrical with respect to the center point CE1 of the virtual first quadrangle Q1. For example, the vertex of the virtual first quadrangle Q1 may be positioned at a center of the first pixel 100, and the vertex of the virtual first quadrangle Q1 may be positioned at a center of the third pixel 300.

Referring to FIG. 1, the second pixel 200 may not be positioned at the center point CE1 of the virtual first quadrangle Q1. Referring to FIG. 1, a center of the second pixel 200 may not coincide with (or may not overlap) the center of the virtual first quadrangle Q1. Referring to FIG. 1, a side of the second pixel 200 may be positioned in contact with a virtual first diagonal line connecting the centers of the first pixels 100, and another side of the second pixel may be positioned in contact with a virtual second diagonal line connecting the centers of the third pixels 300. However, this is only an example, and the second pixel 200 may not be in contact with the first diagonal line and the second diagonal line.

Referring to FIG. 1, lines connecting the second pixels 200 may form a virtual trapezoid TP1. Referring to FIG. 1, distances between the second pixels 200 adjacent to each other in a first direction DR1 may not be the same. For example, as the distances between the second pixels 200 adjacent in the first direction DR1, a minimum distance n1 and a maximum distance m1 between the second pixels 200 may be alternately repeated. The second pixels 200 may be positioned on the same line side by side in the first direction DR1. The second pixels 200 may not be positioned on the same line in a second direction DR2, and may be positioned in a zigzag pattern. The virtual trapezoid TP1 formed by the four adjacent second pixels 200 in FIG. 1 may have a shape in which upper and lower sides parallel to each other are positioned in parallel to the first direction DR1, and two non-parallel sides of the virtual trapezoid TP1 are positioned in the second direction DR2. For example, the second pixels 200 may include a first-second pixel, a second-second pixel, and a third-second pixel that are sequentially disposed on the same line, and the distance m1 between the first-second pixel and the second-second pixel adjacent to each other may be longer than the distance n1 between the second-second pixel and the third-second pixel adjacent to each other.

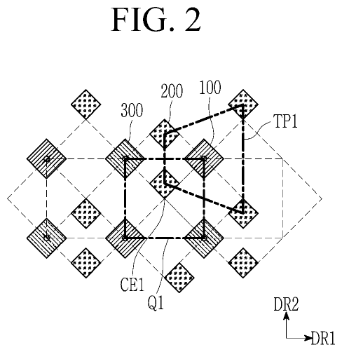

FIG. 2 is a schematic plan view illustrating a pixel arrangement according to another embodiment. Referring to FIG. 2, a display device according to an embodiment may be substantially the same as the embodiment of FIG. 1 except that a direction of a virtual trapezoid TP1 formed by four adjacent second pixels 200 is different from that of the embodiment of FIG. 1. A detailed description of the same constituent elements will be omitted for descriptive convenience. In the embodiment of FIG. 2, two adjacent first pixels 100 and two adjacent third pixels 300 may form a virtual first quadrangle Q1, and centers of the first pixels 100 or centers of the third pixels 300 may be positioned at respective vertexes of the virtual first quadrangle Q1. For example, a center point CE1 of the virtual first quadrangle Q1 may not coincide with (or may not overlap) the center of the second pixel 200, and the four adjacent second pixels 200 may form a virtual trapezoid TP1. For example, the upper and lower sides parallel to each other of the virtual trapezoid TP1 may be positioned parallel to the second direction DR2, and the two non-parallel sides may be positioned in the first direction DR1. In the embodiment of FIG. 2, the second pixels 200 adjacent in the second direction DR2 may be positioned on the same line, and the second pixels 200 adjacent in the first direction DR1 may not be positioned on the same line.

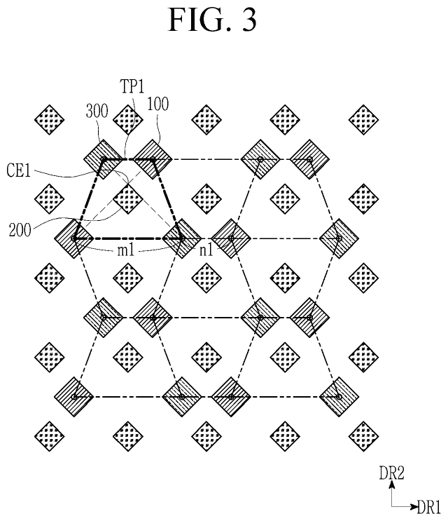

FIG. 3 is a schematic plan view illustrating a pixel arrangement according to another embodiment. Referring to FIG. 3, two first pixels 100 and two third pixels 300 may form a virtual trapezoid TP1. For example, the second pixel 200 may be positioned in the virtual trapezoid TP1. The center point CE1 of the virtual trapezoid TP1 (e.g., an intersection of virtual lines connecting diagonal corners of the virtual trapezoid TP1) may not coincide with (or may not overlap) the center of the second pixel 200. Referring to FIG. 3, a side of the second pixel 200 may be positioned on a first virtual diagonal line connecting the first pixels 100 in the virtual trapezoid TP1, and another side of the second pixel 200 may be positioned on a second virtual diagonal line connecting the third pixels 300 therein.

Referring to FIG. 3, the first pixel 100 and the third pixel 300 parallel to each other in the first direction DR1 may be positioned on the same line. For example, distances between the first pixels 100 and the third pixels 300 parallel to the first direction DR1 may not be the same. For example, the distances between the first pixels 100 and the third pixels 300 may include the minimum distance n1 and the maximum distance m1, which are alternately repeated in the first direction DR1. For example, the first pixels 100 may include a first-first pixel, and the third pixels 300 may include a first-third pixel and a second-third pixel. For example, the first-third pixel, the first-first pixel, and the second-third pixel may be sequentially disposed on the same line, and the distance m1 between the first-first pixel and the first-third pixel adjacent to each other may be longer than the distance n1 between the first-first pixel and the second-third pixel adjacent to each other. For example, the first pixel 100 and the third pixel 300 parallel to each other in the second direction DR2 may not be positioned on the same line, but may be positioned in a zigzag pattern. Referring to FIG. 3, the upper and lower sides parallel to each other of the virtual trapezoid TP1 may be positioned parallel to the first direction DR1, and the two non-parallel sides may be positioned in the second direction DR2.

In the embodiment of FIG. 3, second pixels 200 may be positioned on the same line in the first direction DR1 and the second direction DR2.

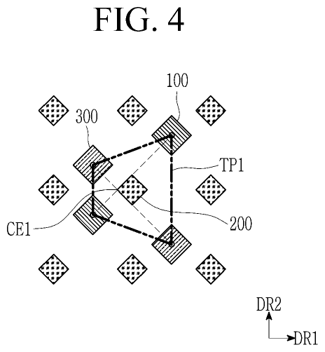

FIG. 4 is a schematic plan view illustrating a pixel arrangement according to another embodiment. An embodiment of FIG. 4 may be substantially the same as the embodiment of FIG. 3 except that a formation direction of a virtual trapezoid TP1 formed by two first pixels 100 and two second third pixels 300 is different from that of the embodiment of FIG. 3. A detailed description of the same constituent elements will be omitted. Referring to FIG. 4, the upper and lower sides parallel to each other of the virtual trapezoid TP1 may be positioned parallel to the second direction DR2, and the two non-parallel sides may be positioned in the first direction DR1. In the embodiment of FIG. 4, the first pixel 100 and the third pixel 300 adjacent in the second direction DR2 may be positioned on the same line, and the first pixel 100 and the third pixel 300 adjacent in the first direction DR1 may not be positioned on the same line.

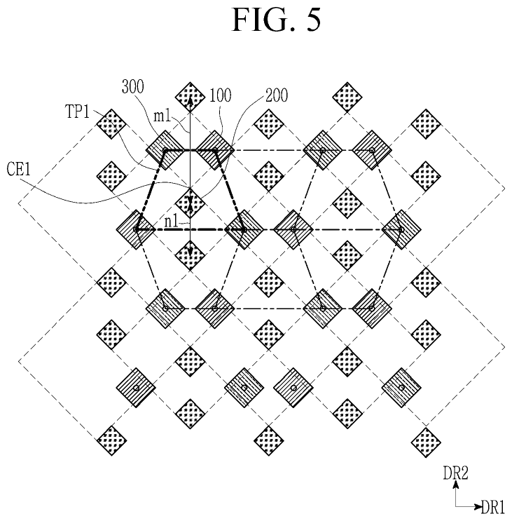

FIG. 5 is a schematic plan view illustrating a pixel arrangement according to another embodiment. An embodiment of FIG. 5 may be substantially the same as the embodiment of FIG. 3 except that the second pixels 200 adjacent in the first direction DR1 are not positioned on the same line. A detailed description of the same constituent elements will be omitted. Referring to FIG. 5, the second pixels 200 adjacent in the second direction DR2 may be positioned on the same line, but the first pixels 100 adjacent in the first direction DR1 may not be positioned on the same line but may be positioned in a zigzag pattern.

For example, the distances between the second pixels 200 adjacent in the second direction DR2 may include the minimum distance n1 and the maximum distance m1, which are alternately repeated in the second direction DR2.

In the embodiment of FIG. 5, the center point CE1 of the virtual trapezoid TP1 formed by two first pixels 100 and two second third pixels 300 may not coincide with (or may not overlap) the center of the second pixel 200 positioned within the virtual trapezoid TP1.

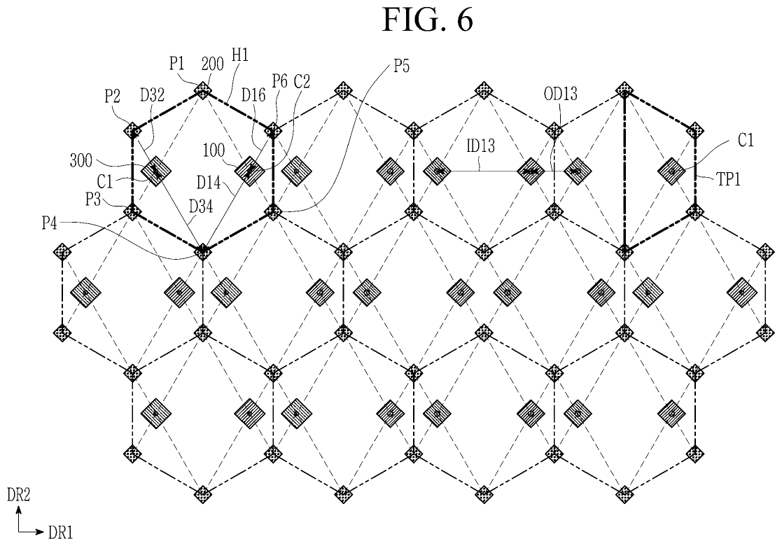

FIG. 6 is a schematic plan view illustrating a pixel arrangement according to another embodiment. Referring to FIG. 6, in a display device according to an embodiment, the second pixels 200 may be positioned at respective vertexes of a virtual hexagon H1. FIG. 6 is a schematic plan view illustrating a first vertex P1, a second vertex P2, a third vertex P3, a fourth vertex P4, a fifth vertex P5, and a sixth vertex P6 of the virtual hexagon H1. Referring to FIG. 6, the third pixel 300 may be positioned at a first intersection point C1 at which a virtual diagonal line connecting the first vertex P1 and the third vertex P3 and a virtual diagonal line connecting the second vertex P2 and the fourth vertex P4 intersect. Positioning at the first intersection point C1 means that the center of the third pixel 300 coincides with (or overlaps) the first intersection point C1. Referring to FIG. 6, the first pixel 100 may be positioned at a second intersection point C2 at which a virtual diagonal line connecting the first vertex P1 and the fifth vertex P5 and a virtual diagonal line connecting the fourth vertex P4 and the sixth vertex P6 intersect. FIG. 6 illustrates a configuration in which the third pixel 300 is positioned at the first intersection point C1 and the first pixel 100 is positioned at the second intersection point C2, but the positions of the first pixel 100 and the third pixel 300 may be opposite to each other. For example, the first pixel 100 may be positioned at the first intersection point C1, and the third pixel 300 may be positioned at the second intersection point C2.

Referring to FIG. 6, the virtual hexagon H1 may include six second pixels 200 positioned at the vertexes thereof, and one first pixel 100 and one third pixel 300 positioned therein. For example, a distance D32 between the third pixel 300 and the second pixel 200 positioned at the second vertex P2 and a distance D34 between the third pixel 300 and the second pixel 200 positioned at the fourth vertex P4 may be different. In the description, a distance between pixels means a distance between a center of a pixel and a center of another pixel.

For example, a distance D16 between the first pixel 100 and the second pixel 200 positioned at the sixth vertex P6 and a distance D14 between the first pixel 100 and the second pixel 200 positioned at the fourth vertex P4 may be different.

Referring to FIG. 6, a distance ID13 between the first pixel 100 and the third pixel 300 positioned in the virtual hexagon H1 may be different from a distance OD13 between the first pixel 100 and the third pixel 300 positioned in another virtual hexagon H1. Referring to FIG. 6, the distance ID13 between the first pixel 100 and the third pixel 300 positioned in the virtual hexagon H1 may be longer than the distance OD13 between the first pixel 100 and the third pixel 300 positioned in another virtual hexagon H1.

Referring to FIG. 6, in case that four adjacent second pixels 200 form the virtual trapezoid TP1, the first pixel 100 or the third pixel 300 may be positioned at the first intersection point C1 of the diagonal lines of the virtual trapezoid TP1. Referring to FIG. 6, the first pixel 100 and the third pixel 300 adjacent in the first direction DR1 may be positioned on the same line, and the first pixel 100 and the third pixel 300 adjacent in the second direction DR2 may not be positioned on the same line, but may be positioned in a zigzag pattern. Although each pixel is illustrated as a quadrangle in FIG. 6, the shape of the pixel is not limited thereto, and may be various, such as a polygon or a circle.

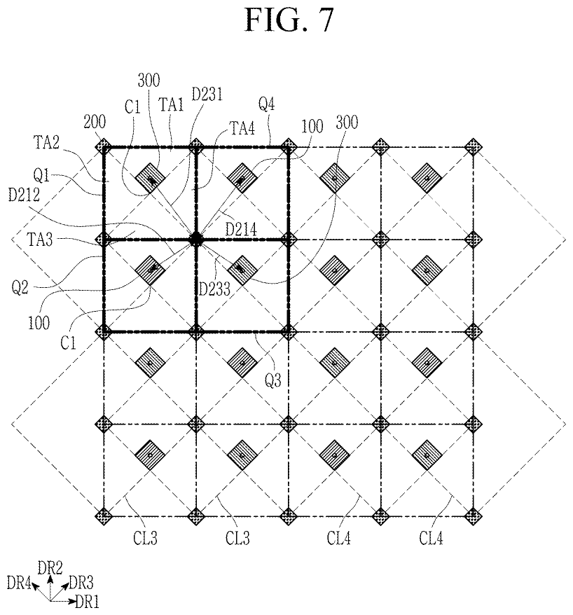

FIG. 7 is a schematic plan view illustrating an arrangement of pixels in a display device according to another embodiment. Referring to FIG. 7, four second pixels 200 adjacent to each other form a virtual first quadrangle Q1. The second pixels 200 adjacent in the first direction DR1 may be positioned on the same line, and the second pixels 200 adjacent in the second direction DR2 may be also positioned on the same line.

For example, the third pixel 300 may be positioned on a virtual diagonal line CL3 in a third direction DR3 connecting the vertexes of the virtual first quadrangle Q1. For example, the third pixel 300 may be positioned on a diagonal line CL4 in a fourth direction DR4 connecting the vertexes of the virtual first quadrangle Q1. Referring to FIG. 7, the third pixel 300 may be positioned in contact with respective diagonal lines at an intersection point C1 at which the diagonal lines intersect within the virtual first quadrangle Q1. For example, the third pixel 300 may be positioned in contact with respective diagonal lines at an intersection point C1 at which the diagonal lines intersect within a virtual second quadrangle Q2.

In case that areas in which the virtual first quadrangle Q1 is divided by the diagonal lines are a first area TA1, a second area TA2, a third area TA3, and a fourth area TA4, respectively, the first pixel 100 or the third pixel 300 may be positioned in the first area TA1 of the virtual first quadrangle Q1.

Referring to FIG. 7, in two first pixels 100 adjacent to the second pixel 200, distances between respective first pixels 100 and the second pixel 200 may be different. FIG. 7 illustrates a virtual first quadrangle Q1, a virtual second quadrangle Q2, a virtual third quadrangle Q3, and a virtual fourth quadrangle Q4. Based on the second pixel 200 included in all of the first, second, third, and fourth quadrangles Q1, Q2, Q3, and Q4, a distance D231 between the second pixel 200 and the third pixel 300 that is positioned in the virtual first quadrangle Q1 and a distance D233 between the second pixel 200 and the third pixel 300 that is positioned in the virtual third quadrangle Q3 may be different.

For example, based on the second pixel 200 included in all of the first, second, third, and fourth quadrangles Q1, Q2, Q3, and Q4, a distance D212 between the second pixel 200 and the first pixel 100 that is positioned in the virtual second quadrangle Q2 and a distance D214 between the second pixel 200 and the first pixel 100 that is positioned in the virtual fourth quadrangle Q4 may be different.

For example, based on the second pixel 200 included in all of the first, second, third, and fourth quadrangles Q1, Q2, Q3, and Q4, a distance D231 between the second pixel 200 and the third pixel 300 that is positioned in the virtual first quadrangle Q1 and a distance D233 between the second pixel 200 and the third pixel 300 that is positioned in the virtual fourth quadrangle Q4 may be different.

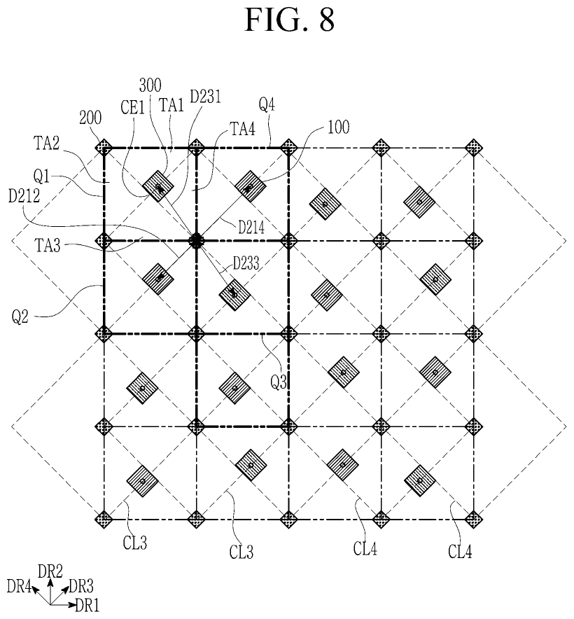

FIG. 8 is a schematic plan view illustrating an arrangement of pixels according to another embodiment. Referring to FIG. 8, the embodiment of FIG. 8 may be substantially the same as the embodiment of FIG. 7 except that the arrangement of the first pixels 100 and the third pixels 300 is different from that of FIG. 7. A detailed description of the same constituent elements will be omitted for descriptive convenience. Referring to FIG. 8, the positions of the first pixels 100 or the third pixels 300 within respective virtual first quadrangles Q1 may be different from those of FIG. 7. Referring to FIG. 7, the first pixel 100 or the third pixel 300 may be positioned in the first area TA1 within the virtual first quadrangle Q1, but in the embodiment of FIG. 8, the first pixel 100 or the third pixel 300 may be entirely positioned in the first area TA1 and the fourth area TA4. Referring to FIG. 8, a side of the first pixel 100 and a side of the third pixel 300 may be positioned on the virtual diagonal line CL4 that crosses the virtual first quadrangle Q1 in the fourth direction DR4. For example, the first pixels 100 may be positioned to alternately contact sides (e.g., opposite sides) of the first pixels 100 to the virtual diagonal line CL4. The third pixels 300 may be also positioned to alternately contact sides (e.g., opposite sides) of the first pixels 100 to the virtual diagonal line CL4. The first pixels 100 adjacent in the fourth direction DR4 may not be positioned on the same line, but may be positioned in a zigzag pattern. For example, the third pixels 300 adjacent in the fourth direction DR4 may not be positioned on the same line, but may be positioned in a zigzag pattern. For example, the center of the second pixel 200 may be positioned on the virtual diagonal line CL4 in the fourth direction DR4.

For example, the centers of the first pixel 100 and the third pixel 300 may be positioned on the virtual diagonal line CL3 that crosses the virtual first quadrangle Q1 in the third direction DR3. Accordingly, the first pixels 100 adjacent in the third direction DR3 may be positioned on the same line. For example, the third pixels 300 adjacent in the third direction DR3 may be positioned on the same line. For example, the center of the second pixel 200 may be positioned on the virtual diagonal line CL3 that crosses the virtual first quadrangle Q1 in the third direction DR3.

FIG. 8 illustrates a virtual first quadrangle Q1, a virtual second quadrangle Q2, a virtual third quadrangle Q3, and a virtual fourth quadrangle Q4. Based on the second pixel 200 included in all of the virtual first, second, third, and fourth quadrangles Q1, Q2, Q3, and Q4, a distance D231 between the second pixel 200 and the third pixel 300 that is positioned in the virtual first quadrangle Q1 and a distance D233 between the second pixel 200 and the third pixel 300 that is positioned in the virtual third quadrangle Q3 may be substantially the same.

For example, based on the second pixel 200 included in all of the virtual first, second, third, and fourth quadrangles Q1, Q2, Q3, and Q4, the distance D212 between the second pixel 200 and the first pixel 100 that is positioned in the virtual second quadrangle Q2 and a distance D214 between the second pixel 200 and the first pixel 100 that is positioned in the fourth quadrangle Q4 may be different.

FIG. 8 illustrates the configuration in which the distances between the first pixels 100 are different and the distances between the third pixels 300 are the same, however, the positions of the first pixel 100 and the third pixel 300 may be opposite to each other. For example, distances between the first pixels 100 may be substantially the same and distances between the third pixels 300 may be different.

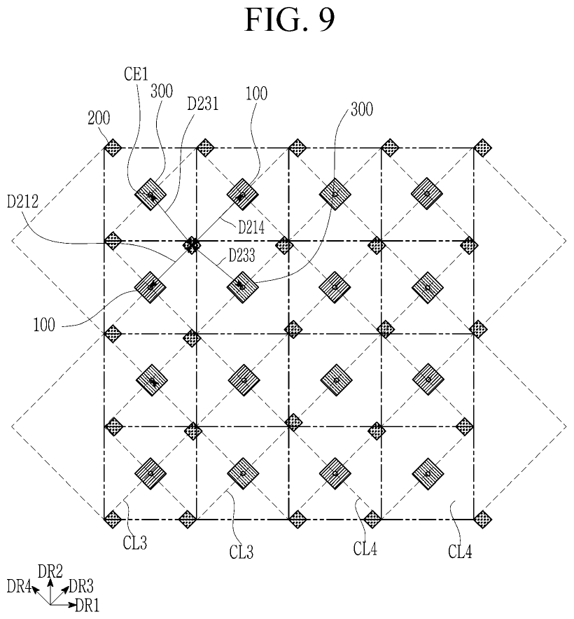

FIG. 9 is a schematic plan view illustrating an arrangement of pixels according to another embodiment. Referring to FIG. 9, the center of the first pixel 100 may be positioned on the virtual diagonal line CL3 in the third direction DR3. For example, the center of the second pixel 200 may be also positioned on the virtual diagonal line CL3 in the third direction DR3. The second pixels 200 adjacent in the third direction DR3 may be positioned on the same line.

The center of the third pixel 300 may be positioned on the virtual diagonal line CIA in the fourth direction DR4. For example, the second pixels 200 may be alternately positioned in left area and right areas based on the virtual diagonal line CL4 in the fourth direction DR4. For example, a side of the second pixel 200 may be positioned on the virtual diagonal line CL4 in the fourth direction DR4. The second pixels 200 adjacent in the fourth direction DR4 may not be positioned on the same line.

Referring to FIG. 9, distances between the third pixels 300 and the second pixels 200 adjacent in the fourth direction DR4 based on the second pixel 200 may be different. Referring to FIG. 9, the distance D231 between the third pixel 300 and the second pixel 200 may be different from the distance D233 between another third pixel 300 and another second pixel 200.

However, referring to FIG. 9, distances between the first pixels 100 and the second pixels 200 adjacent in the third direction DR3 based on the second pixel 200 may be substantially the same. Referring to FIG. 9, the distance D214 between the first pixel 100 and the second pixel 200 may be different from the distance D212 between another first pixel 100 and another second pixel 200.

Although each pixel is illustrated as a quadrangle in FIG. 9, the shape of the pixel is not limited thereto, and may be various, such as a polygon or a circle.

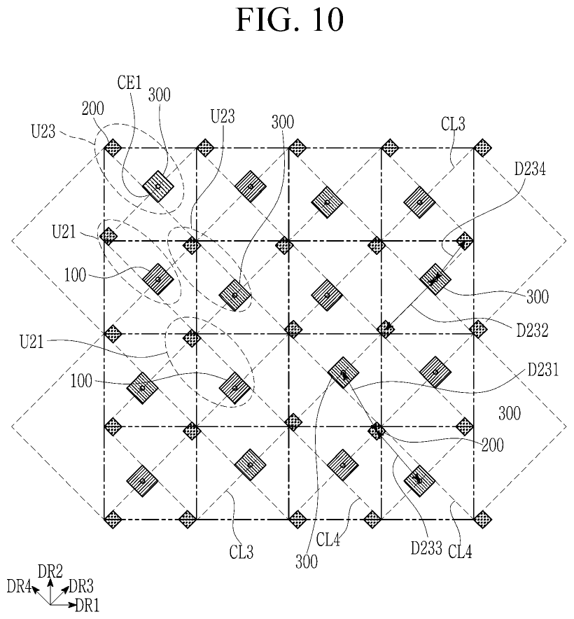

FIG. 10 is a schematic plan view illustrating an arrangement of pixels according to another embodiment. Referring to FIG. 10, the centers of the first pixel 100 and the second pixel 200 may be positioned on the virtual diagonal line CL3 in the third direction DR3. For example, the centers of the third pixel 300 and the second pixel 200 may be positioned on the virtual diagonal line CL3 in the third direction DR3. Accordingly, the pixels adjacent to each other in the third direction DR3 may be positioned on the same line.

Referring back to FIG. 10, the center of the pixel may not be positioned on the virtual diagonal line CL4 in the fourth direction DR4. Referring to FIG. 10, second units U23 of the second pixels 200 and the third pixels 300 may be alternately positioned on the virtual diagonal CL4 in the fourth direction DR4. For example, a side of the second unit U23 may be positioned in contact with the virtual diagonal line CL4, and another side of another second unit U23 may be positioned in contact with the virtual diagonal line CL4.

For example, first units U21 of the second pixels 200 and the first pixels 100 may be alternately positioned on the virtual diagonal line CL4 in the fourth direction DR4. For example, a side of the first unit U21 may be positioned in contact with the virtual diagonal line CL4, and another side of another first unit U21 may be positioned in contact with the virtual diagonal line CL4.

Referring to FIG. 10, the distances between the third pixels 300 and the second pixels 200 adjacent in the fourth direction DR4 based on the second pixel 200 may be different. Referring to FIG. 9, the distance D231 between the third pixel 300 and the second pixel 200 may be different from the distance D233 between another third pixel 300 and another second pixel 200.

For example, the distances between the third pixels 300 and the second pixels 200 adjacent in the third direction DR3 based on the third pixel 300 may be different. Referring to FIG. 10, the distance D234 between the third pixel 300 and the second pixel 200 may be different from the distance D232 between the third pixel 300 and another second pixel 200.

Although each pixel is illustrated as a quadrangle in FIG. 10, the shape of the pixel may be various, such as a polygon or a circle.

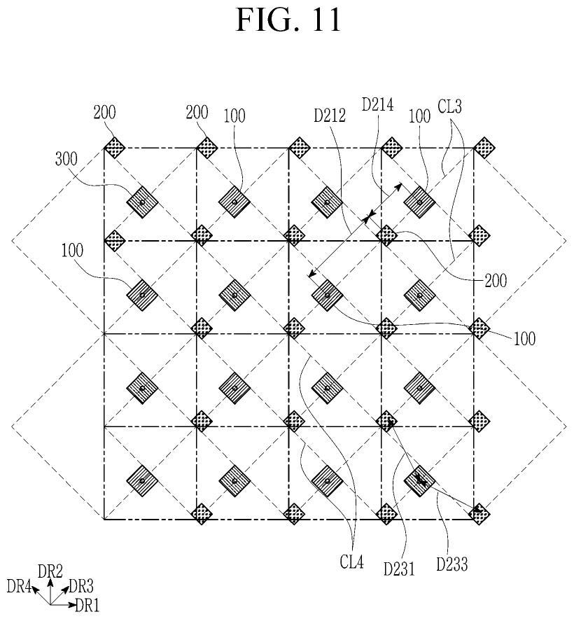

FIG. 11 is a schematic plan view illustrating an arrangement of pixels according to another embodiment. Referring to FIG. 11, the centers of the first pixel 100 and the second pixel 200 may be positioned on the virtual diagonal line CL3 in the third direction DR3. For example, the centers of the third pixel 300 and the second pixel 200 may be positioned on the virtual diagonal line CL3 in the third direction DR3. Accordingly, the pixels adjacent to each other in the third direction DR3 may be positioned on the same line.

For example, the center of the pixel may be not positioned on the virtual diagonal line CL4 in the fourth direction DR4. Referring to FIG. 11, respective pixels may be alternately positioned one by one. For example, the second pixel 200 and the third pixel 300 may be alternately positioned on the virtual diagonal line CL4 in the fourth direction DR4. For example, a side (e.g., left side) of the second pixel 200 may be positioned in contact with the virtual diagonal line CL4, and another side (e.g., right side) of the third pixel 300 may be positioned in contact with the virtual diagonal line CL4.

For example, the second pixels 200 and the first pixels 100 may be alternately positioned on the virtual diagonal line CL4 in the fourth direction DR4. For example, a side (e.g., left side) of the second pixel 200 may be positioned in contact with the virtual diagonal line CL4, and another side (e.g., right side) of the first pixel 100 may be positioned in contact with the virtual diagonal line CL4.

Referring to FIG. 11, the distances between the first pixels 100 and the second pixels 200 adjacent in the third direction DR3 based on the second pixel 200 may be different. Referring to FIG. 10, the distance D214 between the first pixel 100 and the second pixel 200 may be different from the distance D212 between another first pixel 100 and another second pixel 200.

However, referring to FIG. 11, the distances between the third pixels 300 and the second pixels 200 adjacent in the fourth direction DR4 based on the second pixel 200 may be substantially the same. Referring to FIG. 11, the distance D231 between the third pixel 300 and the second pixel 200 may be substantially the same as the distance D233 between the third pixel 300 and another second pixel 200.

Although each pixel is illustrated as a quadrangle in FIG. 11, the shape of the pixels may be various, such as a polygon or a circle.

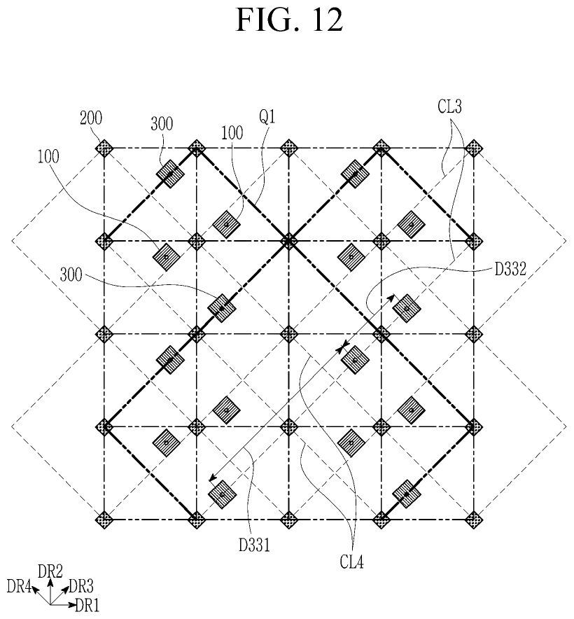

FIG. 12 is a schematic plan view illustrating an arrangement of pixels according to another embodiment. Referring to FIG. 12, four second pixels 200 adjacent to each other may form a virtual first quadrangle Q1. For example, the second pixel 200 may be positioned at the center of the virtual first quadrangle Q1. Referring to FIG. 12, the third pixel 300 may be positioned on the side of the virtual first quadrangle Q1. For example, two third pixels 300 may be symmetrically positioned with respect to the center of the virtual first quadrangle Q1. The first pixel 100 may be positioned within the virtual first quadrangle Q1. For example, two first pixels 100 may be symmetrically positioned with respect to the center of the virtual first quadrangle Q1.

Distances between the third pixels 300 adjacent in the third direction DR3 may be different from each other. Referring to FIG. 12, a distance D331 from a side of one third pixel 300 to a third pixel 300 adjacent thereto and a distance D332 from another side of the one third pixel 300 to a third pixel 300 adjacent thereto may be different from each other.

Referring to FIG. 12, the first pixels 100 and the third pixels 300 may be alternately positioned based on the second direction DR2. Referring to FIG. 12, the second pixels 200 may be positioned on the same line in the first direction DR1 and the second direction DR2. In the case of the pixel arrangement structure of FIG. 12, the pixel may have a shape that is concentrated in a partial area, and such a structure may increase transmittance in the partial area. This is advantageous for application to a display device in which a device such as a sensor or a camera overlaps a display panel.

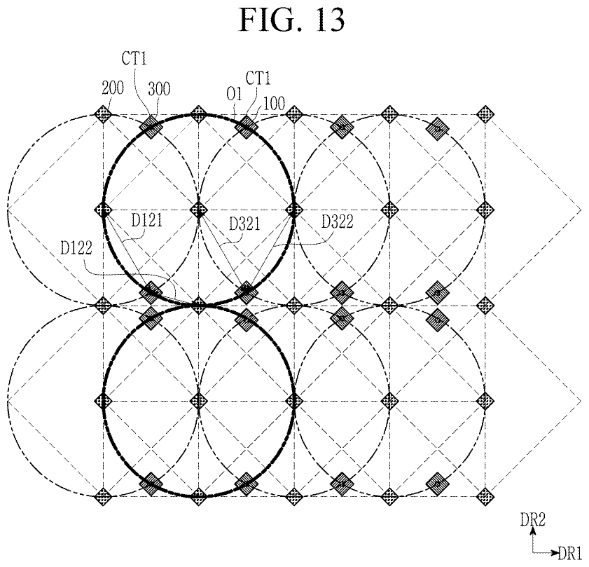

FIG. 13 is a schematic plan view illustrating an arrangement of pixels according to another embodiment. Referring to FIG. 13, a virtual circle O1 centered on each second pixel 200 may be formed. Referring to FIG. 13, only some of the second pixels 200 adjacent in the second direction DR2 may be disposed at the center of the virtual circle O1. In case that the second pixel 200 is disposed at the center of the virtual circle O1, the second pixel 200 adjacent thereto in the second direction DR2 may be disposed at a circumference of the virtual circle O1, not the center of the virtual circle O1, and the second pixel 200 next adjacent thereto may be disposed at a center of another virtual circle O1.

For example, the first pixel 100 or the third pixel 300 may be positioned at a contact point CT1 of respective virtual circles O1. Referring to FIG. 13, in a single virtual circle O1, five second pixels 200, two first pixels 100, and two third pixels 300 may be positioned. For example, one second pixel 200 may be positioned at the center of the virtual circle O1, and the remaining pixels may be positioned along the circumference of the virtual circle O1.

In the virtual circle O1, the first pixel 100 and the third pixel 300 may be positioned between two second pixels 200. For example, a distance D121 between the first pixel 100 and the second pixel 200 and a distance D122 between the first pixel 100 and another second pixel 200 may be different.

For example, in the virtual circle O1, a distance D321 between the third pixel 300 and the second pixel 200 that is positioned at the center of the virtual circle O1 may be substantially the same as a distance D322 between the third pixel 300 and the second pixel 200 adjacent thereto. In the case of the pixel arrangement structure of FIG. 13, the pixel may have a shape that is concentrated in a partial area, and such a structure may increase transmittance in the partial area. This is advantageous for application to a display device in which a device such as a sensor or a camera overlaps a display panel.

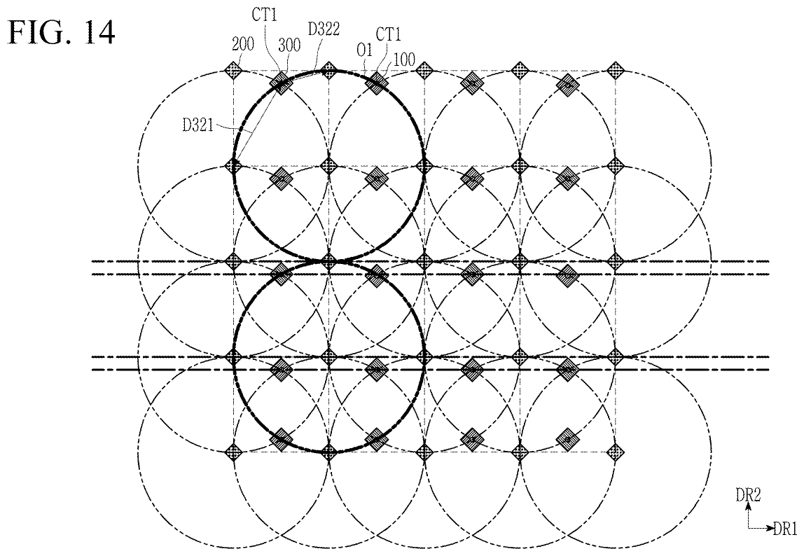

FIG. 14 is a schematic plan view illustrating an arrangement of pixels according to another embodiment. Referring to FIG. 14, a virtual circle O1 centered on each second pixel 200 may be formed. For example, the first pixel 100 or the third pixel 300 may be positioned at the contact point CT1 of respective virtual circles O1.

Three pixels may be positioned in one virtual circle O1, and one first pixel 100, one second pixel 200, and one third pixel 300 may be positioned therein. For example, four second pixels 200, one first pixel 100, and one third pixel 300 may be positioned on the circumference of the virtual circle O1.

Referring to FIG. 14, the second pixels 200 may be positioned on the same line in the first direction DR1. For example, the first pixel 100 and the third pixel 300 positioned at the contact point CT1 of the virtual circle O1 may be also positioned on the same line in the first direction DR1.

Referring to FIG. 14, the third pixel 300 may be positioned between two second pixels 200 along the circumference of the virtual circle O1. For example, a distance D321 between the third pixel 300 and the second pixel 200 and a distance D322 between the third pixel 300 and another second pixel 200 may be different. For example, the first pixel 100 may be also positioned between two second pixels 200, and the distances between the second pixels 200 and the first pixels 100 respectively adjacent to each other may be different.

In the case of the pixel arrangement structure of FIG. 14, the pixel may have a shape that is concentrated in a partial area, and such a structure may increase transmittance in the partial area. This is advantageous for application to a display device in which a device such as a sensor or a camera overlaps a display panel.

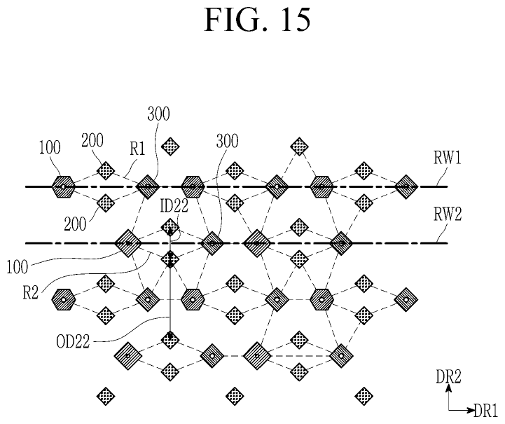

FIG. 15 is a schematic plan view illustrating a pixel arrangement structure according to another embodiment. Referring to FIG. 15, two second pixels 200, one first pixel 100, and one third pixel 300 may form a virtual first rhombus R1. Referring to FIG. 15, the second pixels 200 adjacent in the first direction DR1 may be positioned on the same line, and the second pixels 200 adjacent in the second direction DR2 may also be positioned on the same line. Referring to FIG. 15, the first pixel 100 and the third pixel 300 adjacent in the first direction DR1 may be positioned on the same line. For example, the first pixel 100 and the third pixel 300 adjacent in the second direction DR2 may not be positioned on the same line, but may be positioned in a zigzag pattern.

Referring to FIG. 15, a shape and an area of the first pixel 100 included in the virtual first rhombus R1 positioned in a virtual first row RW1 and a shape and an area of the first pixel 100 included in a virtual second rhombus R2 positioned in a virtual second row RW2 may be different. For example, a shape and an area of the third pixel 300 included in the virtual first rhombus R1 positioned in a virtual first row RW1 and a shape and an area of the third pixel 300 included in a virtual second rhombus R2 positioned in a virtual second row RW2 may be different. Referring to FIG. 15, a distance ID22 between the second pixels 200 positioned in the virtual second rhombus R2 may be shorter than a distance OD22 between the second pixels 200 forming the adjacent virtual first rhombus R1.

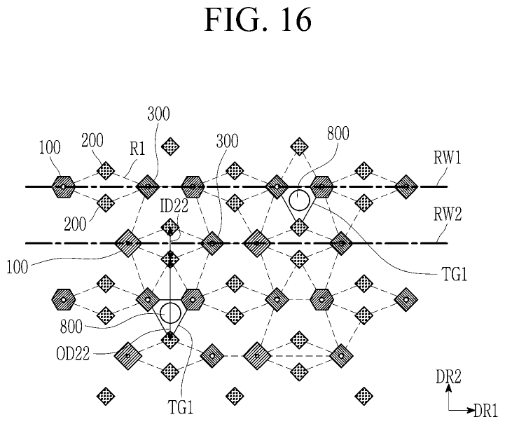

FIG. 16 illustrates a position of a spacer 800 in the display device having the arrangement of FIG. 15. Referring to FIG. 16, the spacer 800 may be positioned within a virtual triangle TG1 formed by the first pixel 100, the second pixel 200, and the third pixel 300 that are closest to each other.

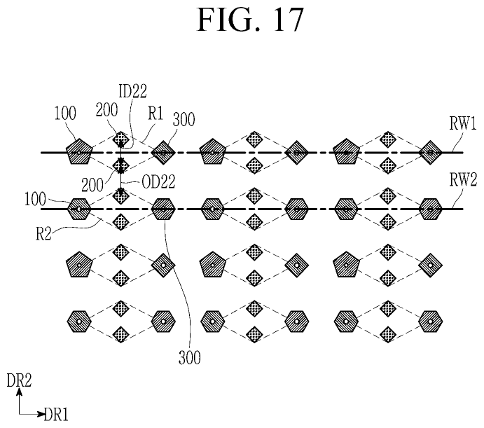

FIG. 17 is a schematic plan view illustrating a pixel arrangement structure according to another embodiment. Referring to FIG. 17, two second pixels 200, one first pixel 100, and one third pixel 300 may form a virtual first rhombus R1. Referring to FIG. 17, the second pixels 200 adjacent in the first direction DR1 may be positioned on the same line, and the second pixels 200 adjacent in the second direction DR2 may also be positioned on the same line. Referring to FIG. 17, the first pixel 100 and the third pixel 300 adjacent in the first direction DR1 may be positioned on the same line. For example, the first pixel 100 and the third pixel 300 adjacent in the second direction DR2 may be positioned on the same line.

Referring to FIG. 17, a shape and an area of the first pixel 100 included in the virtual first rhombus R1 positioned in a virtual first row RW1 and a shape and an area of the first pixel 100 included in a virtual second rhombus R2 positioned in a virtual second row RW2 may be different. For example, a shape and an area of the third pixel 300 included in the virtual first rhombus R1 positioned in a virtual first row RW1 and a shape and an area of the third pixel 300 included in a virtual second rhombus R2 positioned in a virtual second row RW2 may be different.

Referring to FIG. 17, a distance ID22 between the second pixels 200 positioned in the virtual first rhombus R1 may be shorter than a distance OD22 between the second pixels 200 forming the adjacent virtual first rhombus R1.

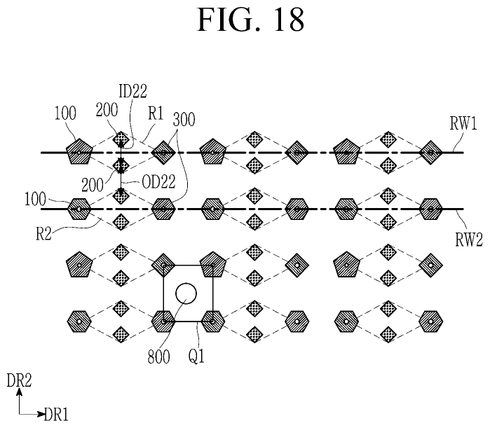

FIG. 18 illustrates a position of a spacer 800 in the display device having the arrangement of FIG. 17. Referring to FIG. 18, the spacer 800 may be positioned within a virtual first quadrangle Q1 formed by the first pixels 100 and the third pixels 300 that are closest to each other.

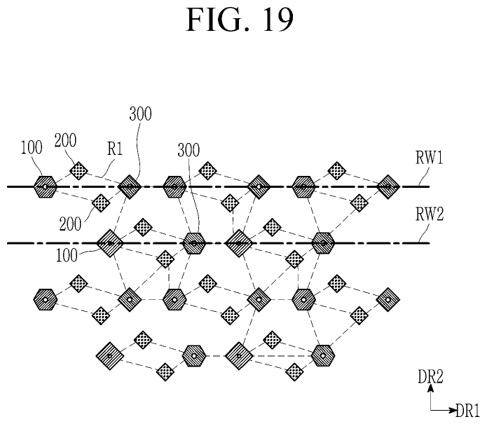

FIG. 19 is a schematic plan view illustrating a pixel arrangement structure according to another embodiment. Referring to FIG. 19, the display device according to an embodiment may be substantially the same as that of FIG. 15 except that a position of the second pixel 200 therein is different from the position of the second pixel 200 in the display device of FIG. 15. A detailed description of the same constituent elements will be omitted for descriptive convenience. Referring to FIG. 15, the second pixels 200 adjacent in the second direction DR2 may not be positioned on the same line.

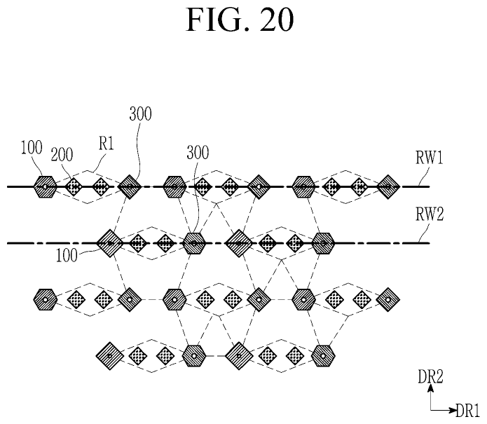

FIG. 20 is a schematic plan view illustrating a pixel arrangement structure according to another embodiment. Referring to FIG. 20, the display device according to an embodiment may be substantially the same as the embodiment of FIG. 15 except that two second pixels 200 positioned in the virtual first rhombus R1 are positioned side by side in the first direction DR1. A detailed description of the same constituent elements will be omitted for descriptive convenience.

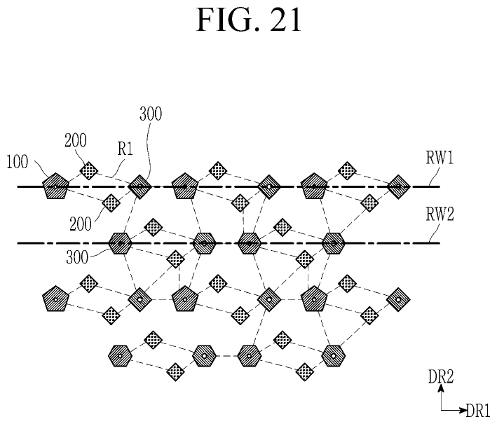

FIG. 21 is a schematic plan view illustrating a pixel arrangement structure according to another embodiment. Referring to FIG. 21, the display device according to an embodiment may be substantially the same as that of FIG. 17 except that a position of the second pixel 200 therein is different from the position of the second pixel 200 in the display device of FIG. 17. A detailed description of the same constituent elements will be omitted for descriptive convenience. Referring to FIG. 17, the second pixels 200 adjacent in the second direction DR2 may not be positioned on the same line.

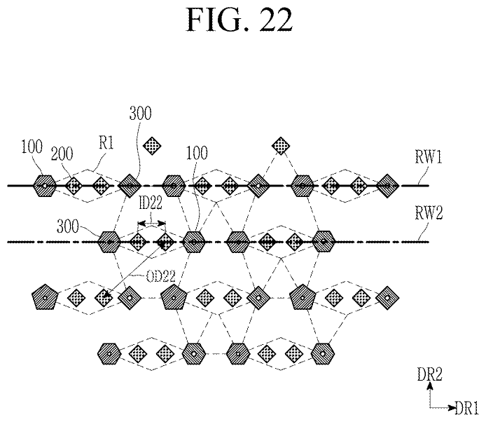

FIG. 22 is a schematic plan view illustrating a pixel arrangement structure according to another embodiment. Referring to FIG. 22, the display device according to an embodiment may be substantially the same as the embodiment of FIG. 17 except that two second pixels 200 positioned in the virtual first rhombus R1 are positioned side by side in the first direction DR1. A detailed description of the same constituent elements will be omitted for descriptive convenience.

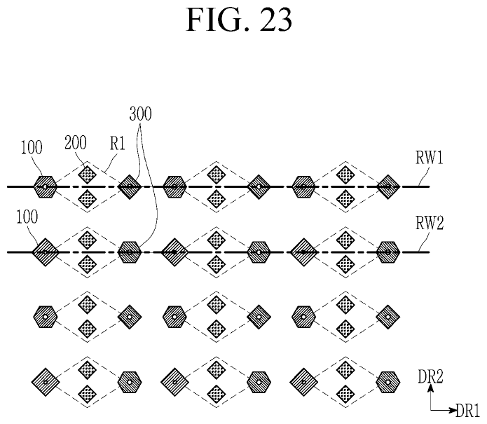

FIG. 23 is a schematic plan view illustrating a pixel arrangement structure according to another embodiment. Referring to FIG. 23, in the display device according to an embodiment, a shape and an area of the first pixel 100 included in the virtual first rhombus R1 positioned in a virtual first row RW1 and a shape and an area of the first pixel 100 included in a virtual second rhombus R2 positioned in a virtual second row RW2 may be different. For example, the shape and the area of the first pixel 100 included in the virtual first rhombus R1 may be substantially the same as the shape and the area of the third pixel 300 included in the virtual second rhombus R2. For example, the shape and the area of the third pixel 300 included in the virtual first rhombus R1 may be substantially the same as the shape and the area of the first pixel 100 included in the virtual second rhombus R2.

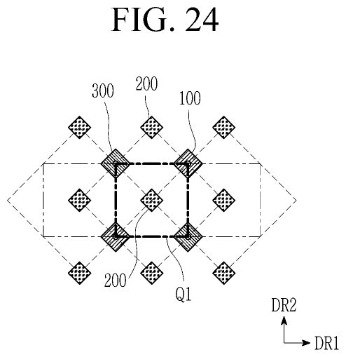

In the embodiments, the arrangement structures of the pixels may be different for respective areas of the display device. For example, some areas of the display device may have an arrangement structure as shown in FIG. 24. Referring to FIG. 24, the second pixel 200 may be positioned at the center of the virtual first quadrangle Q1 formed by two first pixels 100 and three third pixels 300. For example, adjacent first pixels 100 may be positioned on the same line in the first direction DR1 and the second direction DR2. For example, adjacent second pixels 200 may be positioned on the same line in the first direction DR1 and the second direction DR2, and adjacent third pixels 300 may be positioned on the same line in the first direction DR1 and the second direction DR2.

In the display device, some areas of the display device may have the structure shown in FIG. 24, and other areas of the display device may have the structure shown in FIG. 1 to FIG. 23 described above. In case that different dispositions (or arrangements) are required for respective areas in consideration of transmittance of the display device, the disposition (or arrangement) of pixels may be different for some respective areas. For example, an area in which a sensor or a camera is positioned may have a pixel arrangement structure as shown in FIG. 1 to FIG. 23, and an area that does not overlap other modules may have a pixel arrangement structure as shown in FIG. 24. A size of each pixel in the pixel arrangement structure shown in FIG. 1 to FIG. 23 may be larger than that in the pixel arrangement structure shown in FIG. 24.

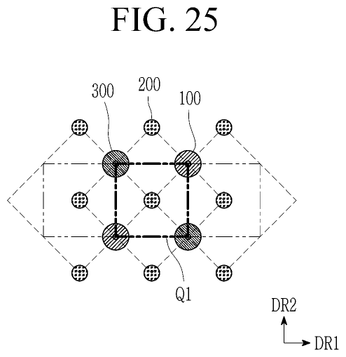

FIG. 25 is a schematic plan view illustrating a pixel arrangement structure according to another embodiment. Referring to FIG. 25, the display device according to an embodiment may be substantially the same as that of FIG. 24 except that a shape of each pixel is not a quadrangle but a circle. A detailed description of the same constituent elements will be omitted for descriptive convenience.

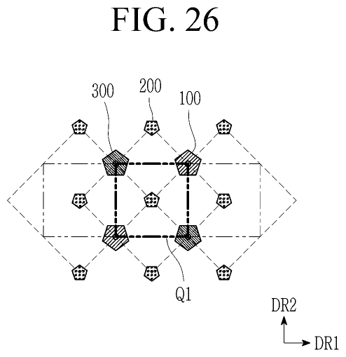

FIG. 26 is a schematic plan view illustrating a pixel arrangement structure according to another embodiment. Referring to FIG. 26, the display device according to an embodiment may be substantially the same as that of FIG. 24 except that a shape of each pixel is not a quadrangle but a pentagon. A detailed description of the same constituent elements will be omitted for descriptive convenience. Referring to FIG. 26, adjacent second pixels 200 may be disposed in a shape in which pentagonal structures may be alternately inverted (or reversed), e.g., in the second direction DR2. For example, in the virtual first quadrangle Q1, the first pixels 100 symmetric at respective vertexes may have a shape in which the pentagonal structures are inverted (or reversed), and the third pixels 300 symmetric at respective vertexes may have a shape in which the pentagonal structures are inverted (or reversed).

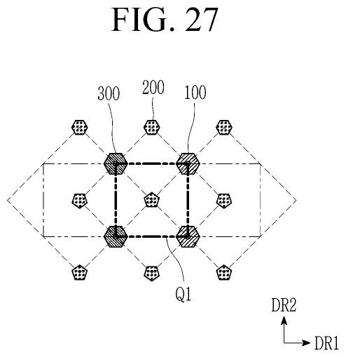

FIG. 27 is a schematic plan view illustrating a pixel arrangement structure according to another embodiment. Referring to FIG. 27, the display device according to an embodiment may be substantially the same as that of FIG. 24 except that a shape of each pixel is not a quadrangle but a hexagon. A detailed description of the same constituent elements will be omitted for descriptive convenience.

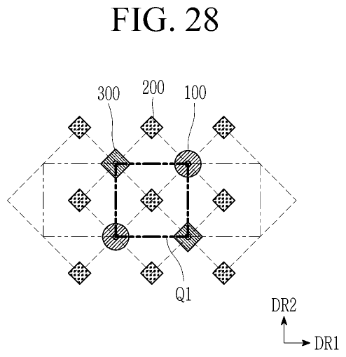

FIG. 28 is a schematic plan view illustrating a pixel arrangement structure according to another embodiment. The embodiment of FIG. 28 may be substantially the same as the embodiment of FIG. 24 except that shapes of pixels are different. A detailed description of the same constituent elements will be omitted for descriptive convenience. Referring to FIG. 28, the second pixel 200 may be a quadrangle, the first pixel 100 may be a circle, and the third pixel 300 may be a quadrangle. However, this is only an example, and the first pixel 100 may be a quadrangle, and the third pixel 300 may be a circle.

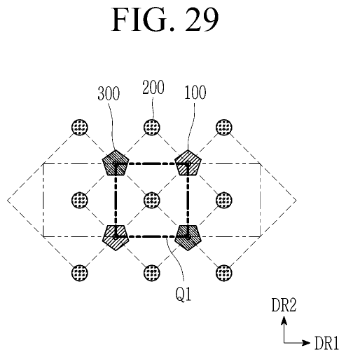

FIG. 29 is a schematic plan view illustrating a pixel arrangement structure according to another embodiment. The embodiment of FIG. 29 may be substantially the same as the embodiment of FIG. 24 except that shapes of pixels are different. A detailed description of the same constituent elements will be omitted for descriptive convenience. Referring to FIG. 29, the second pixel 200 may have a circle shape, the first pixel 100 may have a pentagon shape, and the third pixel 300 may have a pentagon shape. In the virtual first quadrangle Q1, the first pixels 100 symmetric at respective vertexes may have a shape in which the pentagonal structures are inverted (or reversed), and the third pixels 300 symmetric at respective vertexes may have a shape in which the pentagonal structures are inverted (or reversed).

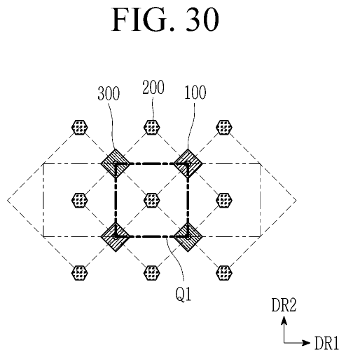

FIG. 30 is a schematic plan view illustrating a pixel arrangement structure according to another embodiment. The embodiment of FIG. 30 may be substantially the same as the embodiment of FIG. 24 except that shapes of pixels are different. A detailed description of the same constituent elements will be omitted for descriptive convenience. Referring to FIG. 30, the second pixel 200 may be a hexagon, and the first pixel 100 and the third pixel 300 may be a quadrangle.

Although various shapes of the first pixel 100, the second pixel 200, and the third pixel 300 are illustrated in FIG. 25 to FIG. 30, this is only an example, and embodiments are not limited thereto.

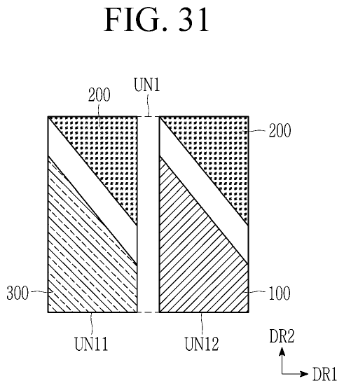

FIG. 31 to FIG. 34 illustrate pixel arrangement structures according to another embodiment. Referring to FIG. 31, a first unit UN1 may include a third pixel 300 and a second pixel 200 spaced apart from each other with a diagonal line therebetween, and a first pixel 100 and a second pixel 200 spaced apart from each other with a diagonal space therebetween. The second pixel 200 may have a triangle shape, and the first pixel 100 and the third pixel 300 may have a trapezoid shape. A hypotenuse of the third pixel 300 and a hypotenuse of the second pixel 200 may be parallel to each other. For example, the hypotenuse of the second pixel 200 and a hypotenuse of the first pixel 100 may be parallel to each other. Referring to FIG. 31, shapes of the first pixel 100 and the third pixel 300 may be substantially the same.

Referring to FIG. 31, the first unit UN1 may include a first sub-unit UN11 and a second sub-unit UN12. The first sub-unit UN11 and the second sub-unit UN12 may have the same shape.

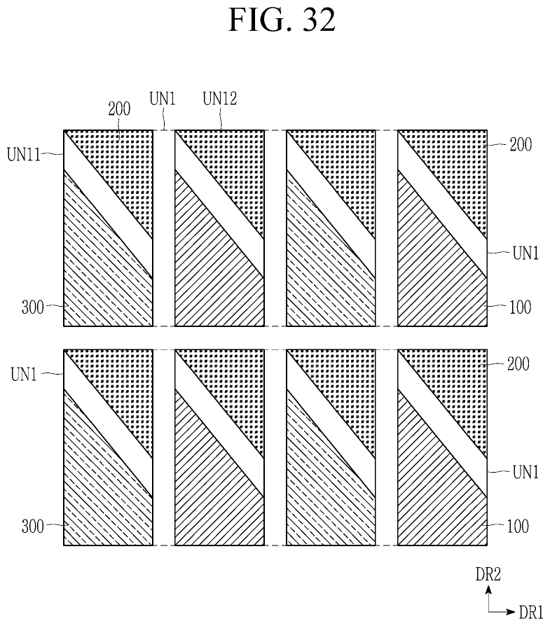

FIG. 32 illustrates a structure in which the first unit UN1 of FIG. 31 is repeatedly arranged. Referring to FIG. 32, the first unit UN1 shown in FIG. 31 may be repeatedly arranged in the same pattern.

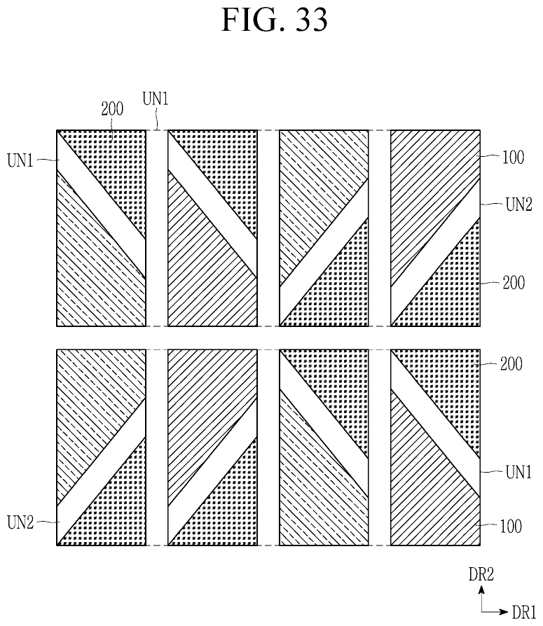

FIG. 33 illustrates a structure including the first unit UN1 of FIG. 31 and a second unit UN2 symmetrical to the first unit UN1. The second unit UN2 may be symmetrical to the first unit UN1 about an imaginary axis extending in the first direction DR1. FIG. 33 illustrates a structure in which the first unit UN1 and the second unit UN2 are alternately positioned.

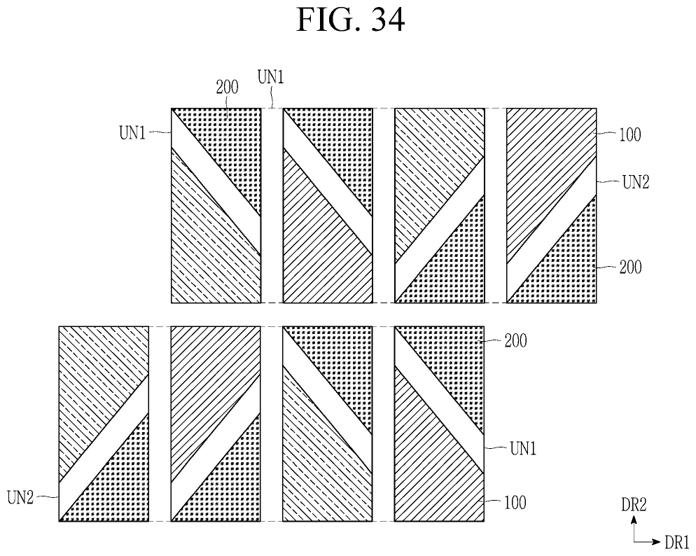

The embodiment of FIG. 34 may be substantially the same as the embodiment of FIG. 33 except that the first unit UN1 and the second unit UN2 are alternately staggered and positioned. A detailed description of the same constituent elements will be omitted for descriptive convenience.

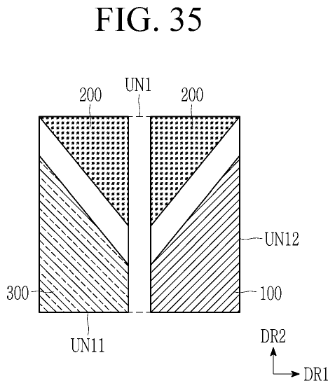

FIG. 35 to FIG. 39 illustrate pixel arrangement structures according to another embodiment. Referring to FIG. 35, a first unit UN1 may include a third pixel 300 and a second pixel 200 spaced apart from each other with a diagonal line therebetween, and a first pixel 100 and a second pixel 200 spaced apart from each other with a diagonal space therebetween. The second pixel 200 may have a triangle shape, and the first pixel 100 and the third pixel 300 may have a trapezoid shape. A hypotenuse of the third pixel 300 and a hypotenuse of the second pixel 200 may be parallel to each other. For example, the hypotenuse of the second pixel 200 and a hypotenuse of the first pixel 100 may be parallel to each other.

Referring to FIG. 35, the first unit UN1 may include a first sub-unit UN11 and a second sub-unit UN12. The first sub-unit UN11 and the second sub-unit UN12 may be symmetrical about an imaginary axis parallel to the second direction DR2. For example, a diagonal space between the first pixel 100 and the second pixel 200 and a diagonal space between the third pixel 300 and the second pixel 200 may form a V shape.

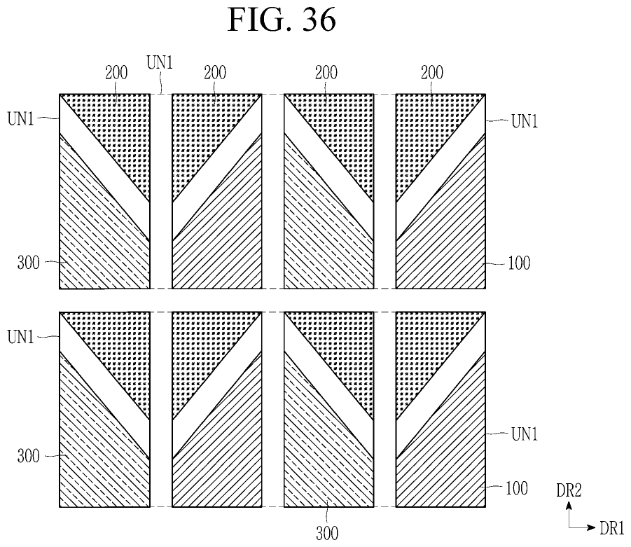

FIG. 36 illustrates a structure in which the first unit UN1 of FIG. 35 is repeatedly arranged. Referring to FIG. 36, the first unit UN1 shown in FIG. 31 may be repeatedly arranged in the same pattern.

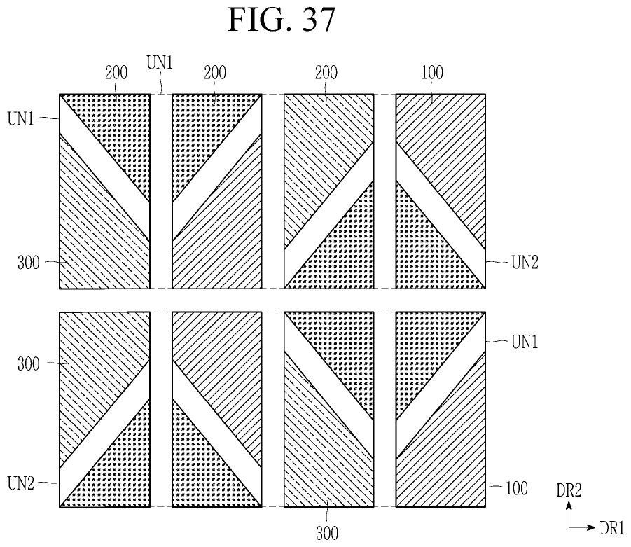

FIG. 37 illustrates a structure including the first unit UN1 of FIG. 35 and a second unit UN2 symmetrical to the first unit UN1. The second unit UN2 may be symmetrical to the first unit UN1 about an imaginary axis parallel to the first direction DR1. FIG. 37 illustrates a structure in which the first unit UN1 and the second unit UN2 are alternately positioned.

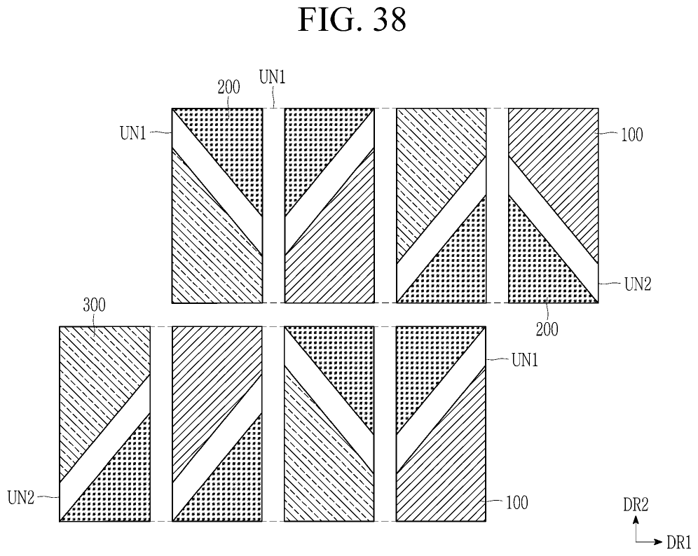

The embodiment of FIG. 38 may be substantially the same as the embodiment of FIG. 37 except that the first unit UN1 and the second unit UN2 are alternately staggered and positioned in the structure of FIG. 35. A detailed description of the same constituent elements will be omitted for descriptive convenience.

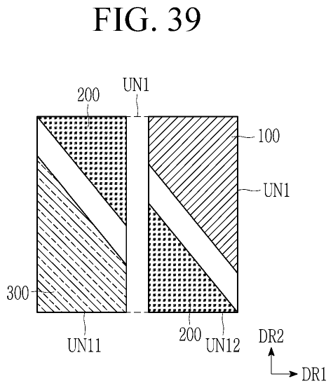

FIGS. 39, 40, 41, and 42 illustrate pixel arrangement structures according to another embodiment. Referring to FIG. 39, a first unit UN1 may include a third pixel 300 and a second pixel 200 spaced apart from each other with a diagonal line therebetween, and a first pixel 100 and a second pixel 200 spaced apart from each other with a diagonal space therebetween. The second pixel 200 may have a triangle shape, and the first pixel 100 and the third pixel 300 may have a trapezoid shape. A hypotenuse of the third pixel 300 and a hypotenuse of the second pixel 200 may be parallel to each other. For example, the hypotenuse of the second pixel 200 and a hypotenuse of the first pixel 100 may be parallel to each other.

Referring to FIG. 39, the first unit UN1 may include a first sub-unit UN11 and a second sub-unit UN12. The first sub-unit UN11 and the second sub-unit UN12 may be symmetrically positioned in a diagonal direction with respect to a center of the first unit UN1. For example, a shape formed by rotating the first sub-unit UN11 by 180 degrees with respect to the center of the first unit UN1 may be the second sub-unit UN12.

Therefore, referring to FIG. 39, a diagonal separation space between the first pixel 100 and the second pixel 200 and a diagonal separation space between the third pixel 300 and the second pixel 200 may not be positioned on the same line.

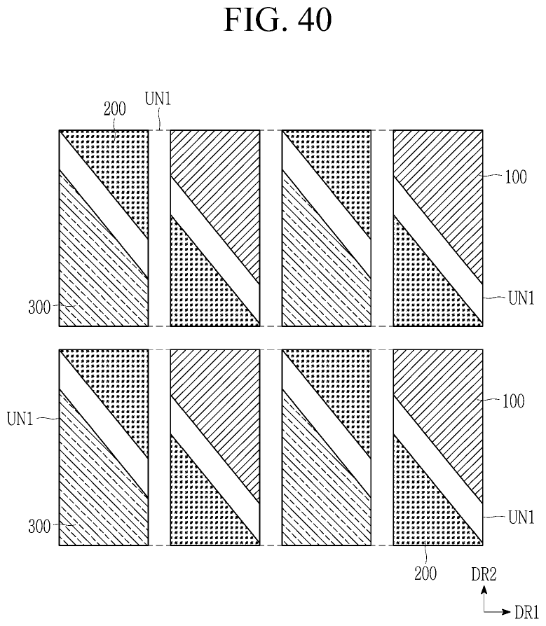

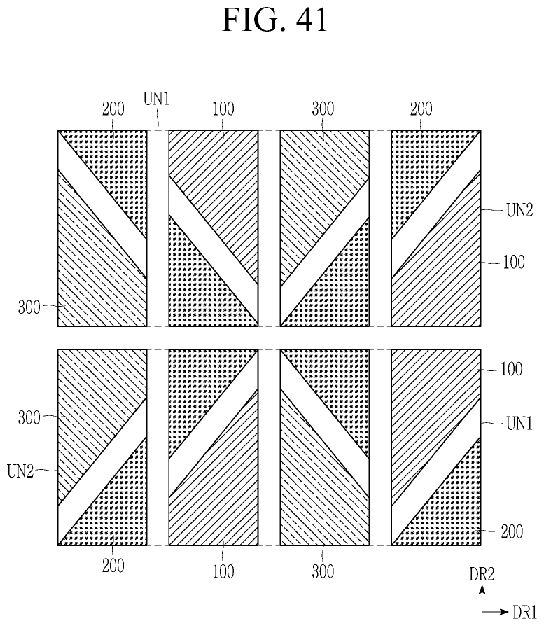

FIG. 40 illustrates a structure in which the first unit UN1 of FIG. 41 is repeatedly arranged. Referring to FIG. 41, the first unit UN1 shown in FIG. 40 may be repeatedly arranged in the same pattern.

FIG. 41 illustrates a structure including the first unit UN1 of FIG. 40 and a second unit UN2 symmetrical to the first unit UN1. The second unit UN2 may be symmetrical to the first unit UN1 about an imaginary axis parallel to the first direction DR1. FIG. 41 illustrates a structure in which the first unit UN1 and the second unit UN2 are alternately positioned.

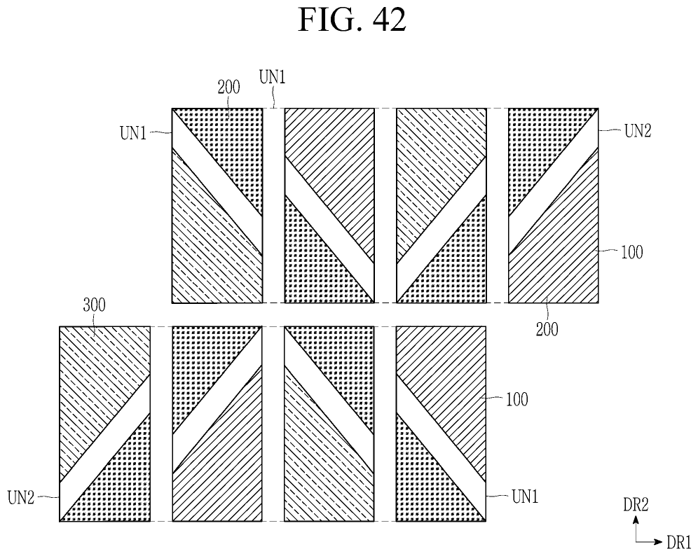

The embodiment of FIG. 42 may be substantially the same as the embodiment of FIG. 41 except that the first unit UN1 and the second unit UN2 are alternately staggered and positioned in the structure of FIG. 40. A detailed description of the same constituent elements will be omitted for descriptive convenience.

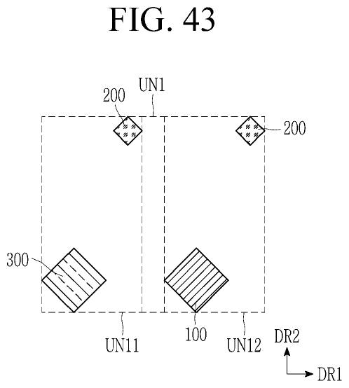

FIG. 43 to FIG. 46 illustrate pixel arrangement structures according to another embodiment. FIG. 43 illustrates a first unit UN1. Referring to FIG. 43, the first unit UN1 may include a third pixel 300 and a second pixel 200, and a first pixel 100 and a second pixel 200 positioned at corners in a diagonal direction of a virtual quadrangle. The second pixels 200 may be positioned on the same line in the first direction DR1, and the first pixel 100 and the third pixel 300 may be positioned on the same line in the first direction DR1.

Referring to FIG. 43, the first unit UN1 may include a first sub-unit UN11 and a second sub-unit UN12. The first sub-unit UN11 and the second sub-unit UN12 may have the same shape.

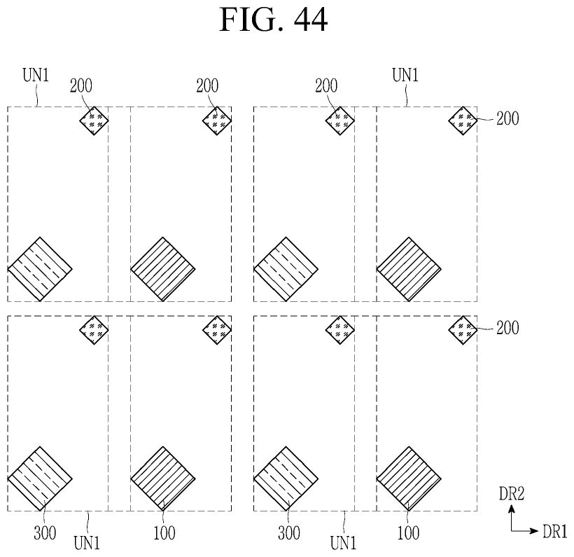

FIG. 44 illustrates a structure in which the first unit UN1 of FIG. 43 is repeatedly arranged. Referring to FIG. 43, the first unit UN1 shown in FIG. 43 may be repeatedly arranged in the same pattern.

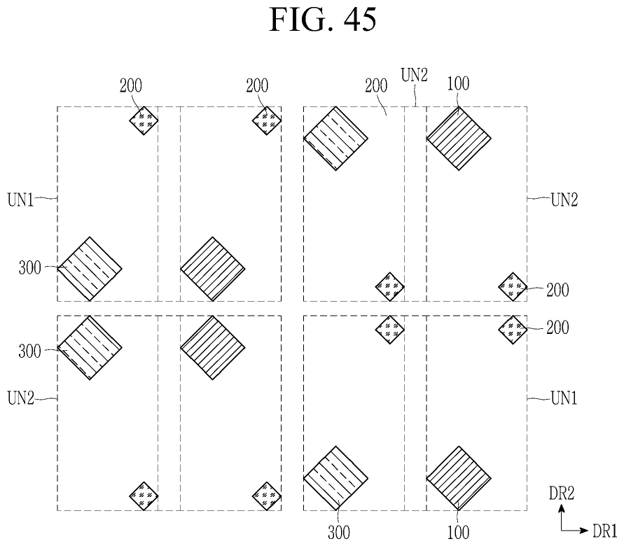

FIG. 45 illustrates a structure including the first unit UN1 of FIG. 43 and a second unit UN2 symmetrical to the first unit UN1. The second unit UN2 may be symmetrical to the first unit UN1 about an imaginary axis parallel to the first direction DR1. FIG. 45 illustrates a structure in which the first unit UN1 and the second unit UN2 are alternately positioned.

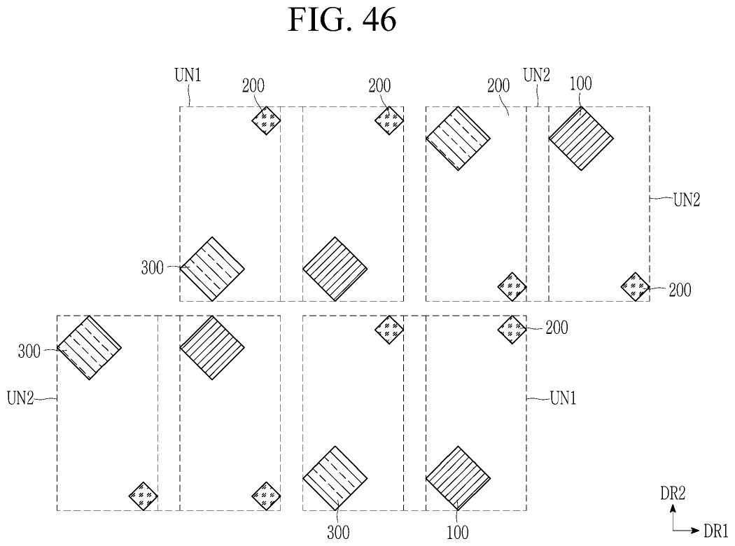

The embodiment of FIG. 46 may be substantially the same as the embodiment of FIG. 45 except that the first unit UN1 and the second unit UN2 are alternately staggered and positioned in the structure of FIG. 45. A detailed description of the same constituent elements will be omitted for descriptive convenience.

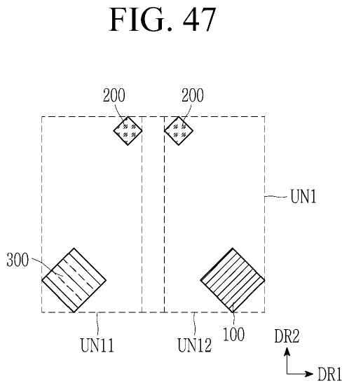

FIG. 47 to FIG. 50 illustrate pixel arrangement structures according to another embodiment. FIG. 47 illustrates a first unit UN1. Referring to FIG. 43, the first unit UN1 may include a third pixel 300 and a second pixel 200, and a first pixel 100 and a second pixel 200 positioned at corners in a diagonal direction of a virtual quadrangle. The second pixels 200 may be positioned on the same line in the first direction DR1, and the first pixel 100 and the third pixel 300 may be positioned on the same line in the first direction DR1.

Referring to FIG. 47, the first unit UN1 may include a first sub-unit UN11 and a second sub-unit UN12. The first sub-unit UN11 and the second sub-unit UN12 may be symmetrical about an imaginary axis parallel to the second direction DR2.

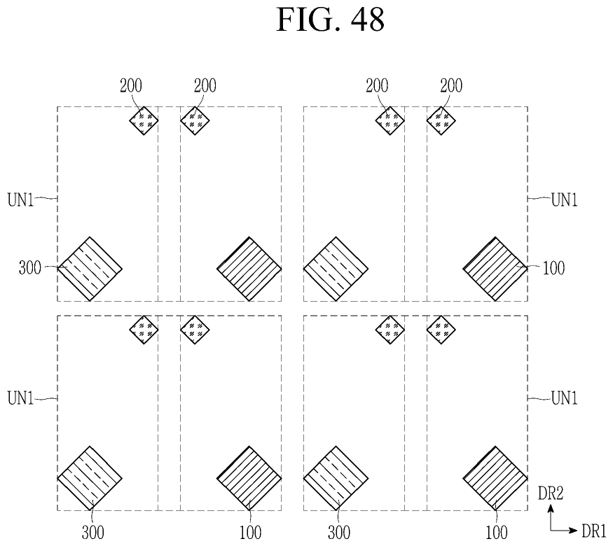

FIG. 48 illustrates a structure in which the first unit UN1 of FIG. 47 is repeatedly arranged. Referring to FIG. 48, the first unit UN1 shown in FIG. 47 may be repeatedly arranged in the same pattern.

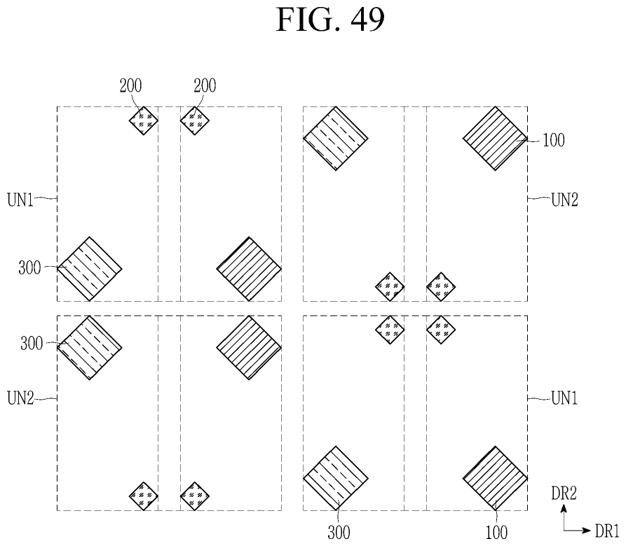

FIG. 49 illustrates a structure including the first unit UN1 of FIG. 47 and a second unit UN2 symmetrical to the first unit UN1. The second unit UN2 may be symmetrical to the first unit UN1 about an imaginary axis parallel to the first direction DR1. FIG. 49 illustrates a structure in which the first unit UN1 and the second unit UN2 are alternately positioned.

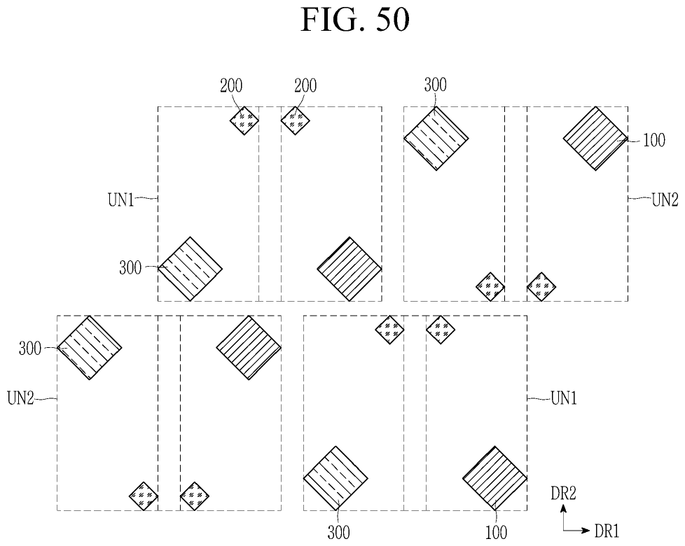

The embodiment of FIG. 50 may be substantially the same as the embodiment of FIG. 49 except that the first unit UN1 and the second unit UN2 are alternately staggered and positioned in the structure of FIG. 49. A detailed description of the same constituent elements will be omitted for descriptive convenience.

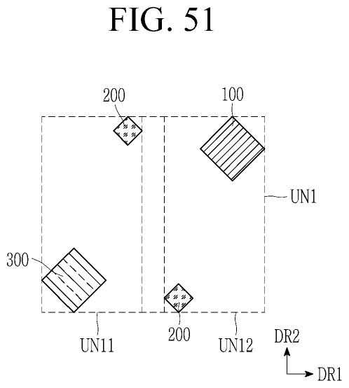

FIG. 51 to FIG. 54 illustrate pixel arrangement structures according to another embodiment. FIG. 51 illustrates a first unit UN1. Referring to FIG. 43, the first unit UN1 may include a third pixel 300 and a second pixel 200, and a first pixel 100 and a second pixel 200 positioned at corners in a diagonal direction of a virtual quadrangle. The second pixels 200 may not be positioned on the same line in the first direction DR1. For example, the first pixel 100 and the third pixel 300 may not be positioned on the same line in the first direction DR1 and the second direction DR2.

Referring to FIG. 51, the first unit UN1 may include a first sub-unit UN11 and a second sub-unit UN12. The first sub-unit UN11 and the second sub-unit UN12 may be symmetrically positioned in a diagonal direction with respect to a center of the first unit UN1. For example, a shape formed by rotating the first sub-unit UN11 by 180 degrees with respect to the center of the first unit UN1 may be the second sub-unit UN12.

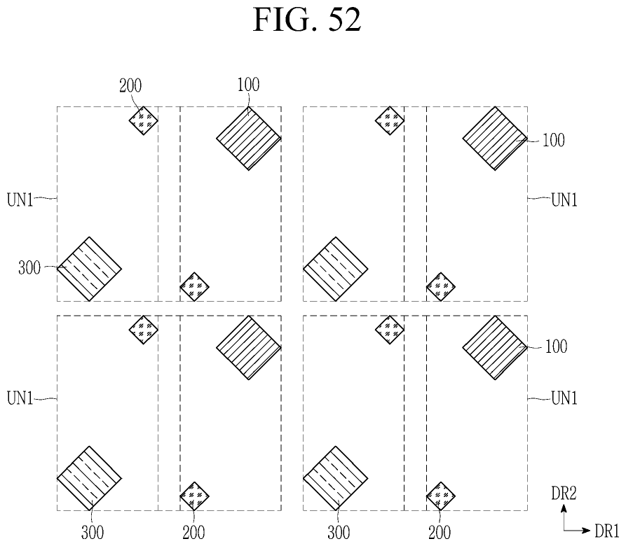

FIG. 52 illustrates a structure in which the first unit UN1 of FIG. 51 is repeatedly arranged. Referring to FIG. 52, the first unit UN1 shown in FIG. 51 may be repeatedly arranged in the same pattern.

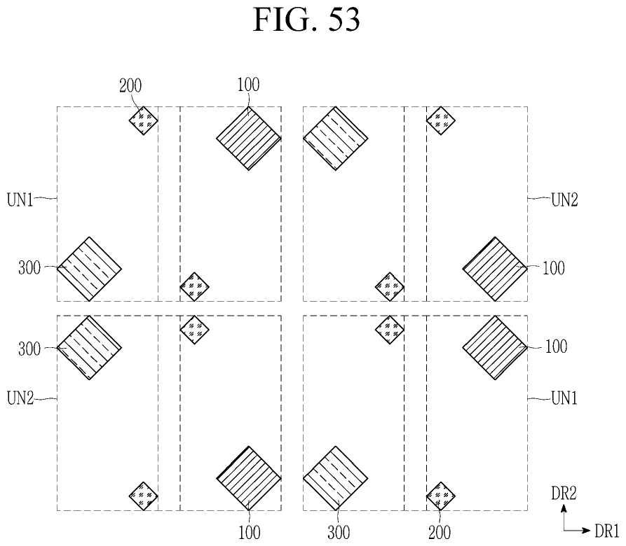

FIG. 53 illustrates a structure including the first unit UN1 of FIG. 51 and a second unit UN2 symmetrical to the first unit UN1. The second unit UN2 may be symmetrical to the first unit UN1 about an imaginary axis parallel to the first direction DR1. FIG. 53 illustrates a structure in which the first unit UN1 and the second unit UN2 are alternately positioned.

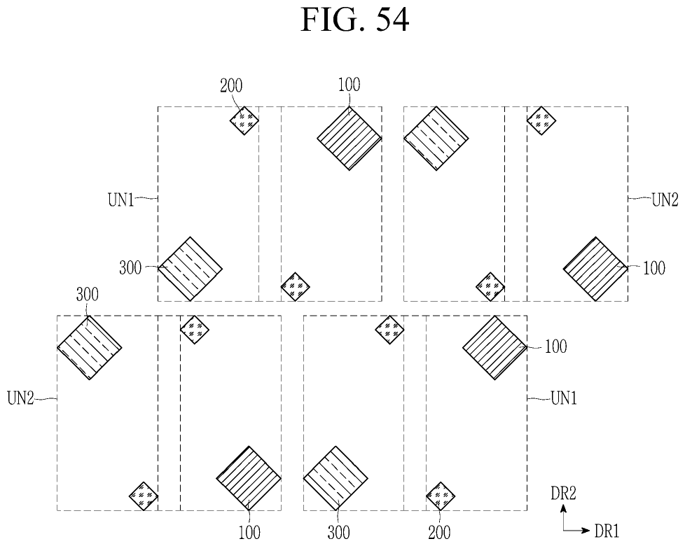

The embodiment of FIG. 54 may be substantially the same as the embodiment of FIG. 53 except that the first unit UN1 and the second unit UN2 are alternately staggered and positioned in the structure of FIG. 53. A detailed description of the same constituent elements will be omitted for descriptive convenience.

Hereinafter, a circuit structure of a pixel configuring each pixel will be described. However, this circuit structure is only an example, and embodiments are not limited thereto.

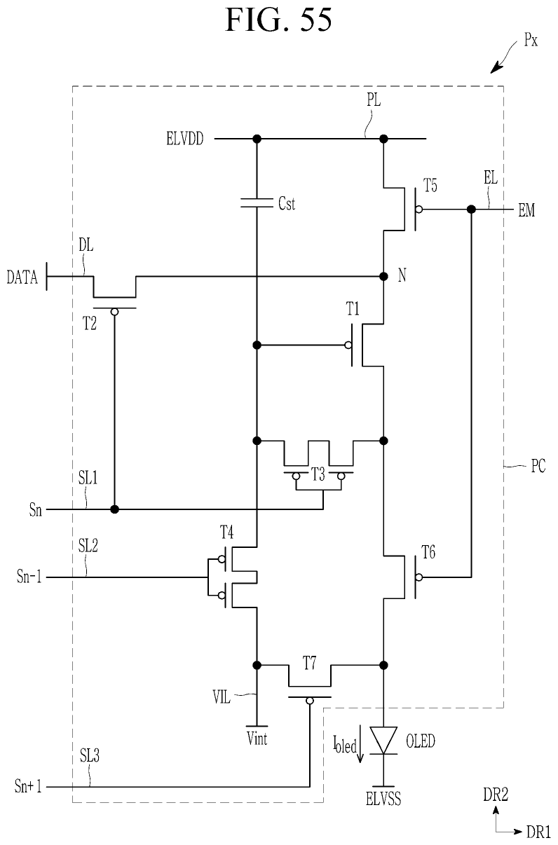

FIG. 55 is a schematic diagram of an equivalent circuit of a pixel according to an embodiment.

Referring to FIG. 55, a pixel circuit PC may include first to seventh transistors T1 to T7, and the first to seventh transistors T1 to T7 may be implemented as thin film transistors. The pixel circuit PC may be connected to a first scan line SL1 transmitting a scan signal Sn, a second scan line SL2 transmitting a previous scan signal Sn−1, a third scan line SL3 transmitting a next scan signal Sn+1, a light emitting control line EL transmitting a light emitting control signal EM, and a data line DL transmitting a data signal DATA. A power voltage line PL may transmit a first power voltage ELVDD to the first transistor T1, and an initialization voltage line VIL may transmit an initialization voltage VINT for initializing the first transistor T1 and a light emitting diode OLED to a gate electrode of the first transistor T1 and the light emitting diode OLED. The first scan line SL1, the second scan line SL2, the third scan line SL3, the light emitting control line EL, and the initialization voltage line VL may extend in the first direction DR1, and may be spaced apart from each other in each row. The data line DL and the power voltage line PL may extend in the second direction DR2, and may be spaced apart from each other in each column. The first transistor T1 may be connected to the power voltage line PL via the fifth transistor T5, and may be connected (e.g., electrically connected) to the light emitting diode OLED via the sixth transistor T6. The first transistor T1 may be a driving transistor, and may receive the data signal DATA according to a switching operation of the second transistor T2 to supply a driving current bow to the light emitting diode OLED. The second transistor T2 may be connected to the first scan line SL1 and the data line DL, and may perform a switching operation of being turned on according to the scan signal Sn transmitted through the first scan line SL1 to transmit the data signal DATA transmitted to the data line DL to a node N. The third transistor T3 may be connected to the light emitting diode OLED via the sixth transistor T6. The third transistor T3 may be turned on according to a first scan signal GW received through the first scan line SL1 to diode-connect the first transistor T1. The fourth transistor T4 may be turned on according to the previous scan signal Sn−1 received through the second scan line SL2 to transmit the initialization voltage VINT from the initialization voltage line VIL to the gate electrode of the first transistor T1 to initialize the gate voltage of the first transistor T1. The fifth transistor T5 and the sixth transistor T6 may be simultaneously turned on according to the light emitting control signal EM received through the light emitting control line EL to form a current path so that the current bow may flow in a direction of the light emitting diode OLED from the power voltage line PL. The seventh transistor T7 may be turned on according to the next scan signal Sn+1 received through the third scan line SL3 to transmit the initialization voltage VINT from the initialization voltage line VIL to the light emitting diode OLED to initialize the light emitting diode OLED. In another example, the seventh transistor T7 may be omitted. A capacitor Cst may be connected to the power voltage line PL and the gate electrode of the first transistor T1 to store and maintain a voltage corresponding to a voltage difference between respective terminals of the capacitor Cst, thereby maintaining a voltage applied to the gate electrode of the first transistor T1. The light emitting diode OLED may include a pixel electrode and an opposite electrode (e.g., a common electrode), and the opposite electrode may receive a second power voltage ELVSS. The light emitting diode OLED may receive the driving current bow from the first transistor T1 to emit light, thereby displaying an image. Referring to FIG. 55, the third transistor T3 and the fourth transistor T4 may have double gate electrodes, but the third transistor T3 and the fourth transistor T4 may have a single gate electrode. Referring to FIG. 55, the seventh transistor T7 may receive the next scan signal Sn+1 through the third scan line SL3, but the seventh transistor T7 may be connected to the second scan line SL2 to receive the previous scan signal Sn−1.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate; and
a plurality of first pixels, a plurality of second pixels, and a plurality of third pixels, positioned on the substrate, wherein
two of the plurality of first pixels and two of the plurality of third pixels are disposed at corners of a virtual first quadrangle,
one of the plurality of second pixels is disposed within the virtual first quadrangle, and
a center of the virtual first quadrangle does not overlap a center of the one of the plurality of second pixels.

2. The display device of claim 1, wherein four of the plurality of second pixels are disposed at corners of a virtual second quadrangle.

3. The display device of claim 2, wherein at least one of the virtual first quadrangle and the virtual second quadrangle is a trapezoid.

4. The display device of claim 1, wherein
the plurality of first pixels and the plurality of third pixels are alternately disposed one by one along a first direction, and
the plurality of first pixels and the plurality of third pixels are alternately disposed one by one along a second direction perpendicular to the first direction.

5. The display device of claim 3, wherein
the plurality of second pixels include a first-second pixel, a second-second pixel, and a third-second pixel that are sequentially disposed on a same line, and a distance between the first-second pixel and the second-second pixel adjacent to each other is different from a distance between the second-second pixel and the third-second pixel adjacent to each other.

6. The display device of claim 3, wherein
the plurality of first pixels include a first-first pixel,
the plurality of third pixels include a first-third pixel and a second-third pixel,
the first-third pixel, the first-first pixel, and the second-third pixel are sequentially disposed on a same line, and
a distance between the first-first pixel and the first-third pixel adjacent to each other is different from a distance between the first-first pixel and the second-third pixel adjacent to each other.

7. The display device of claim 2, wherein
the virtual first quadrangle and the virtual second quadrangle are trapezoids,
the plurality of first pixels and the plurality of third pixels are alternately disposed one by one along a first direction,
a minimum distance and a maximum distance among distances between the plurality of first pixels and the plurality of third pixels in the first direction are alternately repeated, and
a minimum distance and a maximum distance among distances between the plurality of second pixels adjacent in a second direction perpendicular to the first direction are alternately repeated.

8. A display device comprising:
a substrate; and
a plurality of first pixels, a plurality of second pixels, and a plurality of third pixels, disposed on the substrate, wherein
four of the plurality of second pixels are disposed at corners of a virtual first trapezoid,
four of the plurality of second pixels are disposed at corners of a virtual second trapezoid,
a long side of the virtual first trapezoid and a long side of the virtual second trapezoid overlap each other,
each of the plurality of first pixels is disposed at a center of the virtual first trapezoid, and
each of the plurality of third pixels is disposed at a center of the virtual second trapezoid.

9. A display device comprising:
a substrate; and
a plurality of first pixels, a plurality of second pixels, and a plurality of third pixels, disposed on the substrate, wherein
four of the plurality of second pixels are disposed at corer areas of a virtual first quadrangle,
one of the plurality of first pixels or one of the plurality of third pixels is disposed in the virtual first quadrangle, and
a center of the one of the plurality of first pixels or a center of the one of the plurality of third pixels disposed in the virtual first quadrangle does not overlap a center of the virtual first quadrangle.

10. The display device of claim 9, wherein a distance between one of the plurality of second pixels and one of the plurality of first pixels adjacent to each other in a direction is different from a distance between the one of the plurality of second pixels and another one of the plurality of first pixels adjacent to each other in the direction.

11. The display device of claim 9, wherein a distance between one of the plurality of second pixels and one of the plurality of third pixels adjacent to each other in a direction is different from a distance between the one of the plurality of second pixels and another one of the plurality of third pixels adjacent to each other in the direction.

12. The display device of claim 9, wherein
a first diagonal line of the virtual first quadrangle passes through a center of one of the plurality of second pixels, and
the plurality of first pixels and the plurality of third pixels are alternately disposed in left areas and right areas with respect to the first diagonal line.

13. The display device of claim 9, wherein
a first diagonal line of the virtual first quadrangle passes through a center of the one of the plurality of first pixels or the one of the plurality of third pixels, and
the plurality of second pixels are alternately disposed in left areas and right areas with respect to the first diagonal line.

14. The display device of claim 9, wherein
a first unit pixel includes one of the plurality of first pixels and one of the plurality of second pixels, and
the first unit pixels are alternately disposed in left areas and right areas with respect to a first diagonal line of the virtual first quadrangle.

15. The display device of claim 9, wherein
four of the plurality of second pixels are disposed at corners of a virtual first rhombus,
one of the plurality of second pixels is disposed at a center of the virtual first rhombus,
two of the plurality of first pixels or two of the plurality of third pixels are disposed on a side of the virtual first rhombus, and
the other two of the plurality of first pixels or the other two of the plurality of third pixels are disposed in the virtual first rhombus.

16. The display device of claim 15, wherein
two of the four of the plurality of second pixels and the other two of the plurality of second pixels are disposed at corners of a virtual second rhombus that contacts the virtual first rhombus,
another one of the plurality of second pixels is disposed in a center of the virtual second rhombus,
the other two of the plurality of first pixels or the other two of the plurality of third pixels are disposed on a side of the virtual second rhombus, and
the plurality of first pixels or the plurality of third pixels are not disposed in the virtual second rhombus.

17. The display device of claim 9, wherein the one of the plurality of first pixels or the one of the plurality of third pixels is disposed on a virtual arc that connects two vertexes of the virtual first quadrangle.

18. A display device comprising:
a substrate including a first area and a second area;
a plurality of first pixels, a plurality of second pixels, and a plurality of third pixels, disposed on the substrate, wherein
two of the plurality of first pixels and two of the plurality of third pixels are disposed at corners of a virtual first quadrangle in the first area,
one of the plurality of second pixels is disposed within the virtual first quadrangle,
a center of the virtual first quadrangle overlaps a center of the one of the plurality of second pixels, and
one of the plurality of first pixels, one of the plurality of third pixels, and two of the plurality of second pixels are disposed at corners of a virtual first rhombus in the second area.

19. The display device of claim 18, wherein the one of the plurality of first pixels and the one of the plurality of third pixels are disposed at two vertexes of the virtual first rhombus in a first direction in the second area.

20. The display device of claim 19, wherein the two of the plurality of second pixels are disposed at the other two vertexes of the virtual first rhombus in a second direction in the second area.

21. The display device of claim 19, wherein the two of the plurality of second pixels are disposed on a side of the virtual first rhombus.

22. The display device of claim 19, wherein the two of the plurality of second pixels are disposed in the virtual first rhombus.

23. The display device of claim 18, wherein
another one of the plurality of first pixels, another one of the plurality of third pixels, and the other two of the plurality of second pixels are disposed at corners of a virtual second rhombus, and
a shape of the one of the plurality of first pixels in the virtual first rhombus disposed in a first row and a shape of the another one of the plurality of third pixels in the virtual second rhombus disposed in a second row are substantially same as each other.

24. The display device of claim 23, wherein
the shape of the one of the plurality of first pixels in the virtual first rhombus is different from a shape of the one of the plurality of third pixels in the virtual first rhombus, and
a shape of the another one of the plurality of first pixels in the virtual second rhombus is different from a shape of the another one of the plurality of third pixels in the virtual second rhombus.

25. The display device of claim 23, wherein the virtual first rhombus and the virtual second rhombus are not disposed on a same line in a second direction.

26. The display device of claim 25, wherein a spacer is disposed in a virtual triangle including corners, in which one of the plurality of first pixels, one of the plurality of second pixels, and one of the plurality of third pixels that are adjacent to each other at a shortest distance.

27. The display device of claim 23, wherein the virtual first rhombus and the virtual second rhombus are disposed on a same line in a second direction.

28. The display device of claim 27, wherein a spacer is disposed in a virtual quadrangle including corners, in which two of the plurality of first pixels and two of the plurality of third pixels that are adjacent to each other at a shortest distance.

29. The display device of claim 18, wherein shapes of each of the plurality of first pixels, each of the plurality of second pixels, and each of the plurality of third pixels are one of a circle, a quadrangle, a pentagon, and a hexagon.

30. A display device comprising:
a substrate; and
a plurality of first pixels, a plurality of second pixels, and a plurality of third pixels disposed on the substrate, wherein
two of the plurality of second pixels, one of plurality of first pixels, and one of the plurality of third pixels form a first unit,
the first unit includes:
a first sub-unit including the one of the plurality of first pixels and one of the two of the plurality of second pixels; and
a second sub-unit including the one of the plurality of third pixels and another one of the two of the plurality of second pixels, and
a size of each of the plurality of second pixels is smaller than sizes of the plurality of first pixels and the plurality of third pixels.

31. The display device of claim 30, wherein shapes of the first sub-unit and the second sub-unit are substantially same as each other.

32. The display device of claim 30, wherein the first sub-unit and the second sub-unit have shapes that are symmetrical to each other with respect to a virtual straight line disposed between the first sub-unit and the second sub-unit.

33. The display device of claim 30, wherein the first sub-unit and the second sub-unit have shapes that are 180 degrees symmetrical with respect to a center point of the first unit.

34. The display device of claim 30, wherein
the other two of the plurality of second pixels, another one of the plurality of first pixels, and another one of the plurality of third pixels form a second unit, and
shapes of the first unit and the second unit are substantially same as each other.

35. The display device of claim 30, wherein
the other two of the plurality of second pixels, another one of the plurality of first pixels, and another one of the plurality of third pixels form a second unit, and
the first unit and the second unit have shapes that are symmetrical to each other with respect to a virtual straight line between the first unit and the second unit.

36. The display device of claim 30, wherein
a shape of each of the plurality of second pixels is a triangle, and
a shape of each of the plurality of first pixels and a shape of each of the third pixels are trapezoids.

37. The display device of claim 30, wherein a shape of each of the plurality of first pixels, a shape of each of the plurality of second pixels, and a shape of each of the plurality of third pixels are rhombuses.
